(19) United States
(12) Patent Application Publication
(10) Pub. No.: US 2024/0273983 A1
(43) Pub. Date: Aug. 15, 2024

(54) FIXTURE, ACTUATOR WITH FIXTURE, AND DETECTION SWITCH

(71) Applicant: PANASONIC INTELLECTUAL PROPERTY MANAGEMENT CO., LTD., Kadoma-shi, Osaka (JP)

(72) Inventor: Takeru Kobayashi, Aichi (JP)

(73) Assignee: PANASONIC INTELLECTUAL PROPERTY MANAGEMENT CO., LTD., Kadoma-shi, Osaka (JP)

(21) Appl. No.: 18/570,392

(22) PCT Filed: May 20, 2022
(86) PCT No.: PCT/JP2022/020995

§ 371 Date: Dec. 14, 2023

(30) Foreign Application Priority Data
Jul. 2, 2021 (JP) 2021-110857

(51) Int. Cl. G08B 13/08; G08B 5/36

(52) U.S. Cl. CPC G08B 13/08; G08B 5/36

(57) ABSTRACT

A fixture for mounting a maintenance-use actuator to a sensor main body of a detection switch includes a holding portion configured to hold the actuator that communicates with the sensor main body when a distance to the sensor main body is within a predetermined distance, a mounted portion detachably mounted to the sensor main body in a manner of maintaining the distance between the actuator held by the holding portion and the sensor main body within the predetermined distance, a main body frame connecting the holding portion and the mounted portion and extending along a first direction, and a protrusion protruding and extending from the main body frame along a third direction perpendicular to the first direction and a second direction from the fixture toward the sensor main body in a mounted state where the fixture is mounted to the sensor main body.

### TECHNICAL FIELD

The present disclosure relates to a fixture, an actuator with a fixture, and a detection switch.

### BACKGROUND ART

In the related art, a detection switch is known which is mounted to a front door of a machine tool, a door portion of a fence around an industrial robot, and the like, and detects opening and closing of the door. In the detection switch, a dedicated actuator mounted to the door (on a movable side) approaches a sensor main body by closing the door, and transmits a signal when a detection element in the main body is detected. In the related art, it is known that in a detection switch including a sensor main body and an actuator, the sensor main body includes a display unit that detects opening and closing of a door and displays an opened and closed state of the door (see Patent Literature 1).

### CITATION LIST

### Patent Literature

PTL 1: JP2019-139877A

### SUMMARY OF INVENTION

### Technical Problem

When maintenance and inspection work (maintenance work) is performed inside a door to which a detection switch in the related art is mounted, it is conceivable that a maintenance-use actuator is prepared in addition to an actuator provided in the door. In this case, there is a possibility that the detection accuracy of the detection switch when the maintenance work is performed decreases, and smooth progress of the maintenance becomes difficult.

The present disclosure provides a fixture, an actuator with a fixture, and a detection switch, by using the fixture, the actuator with a fixture, and the detection switch, erroneous detection of the detection switch can be restrained during the maintenance work performed inside the door to which the detection switch is mounted, and the maintenance work can be smoothly progressed.

### Solution to Problem

An aspect of the present disclosure is a fixture for mounting a maintenance-use actuator to a sensor main body of a detection switch, the fixture includes a holding portion configured to hold the actuator that communicates with the sensor main body when a distance to the sensor main body is within a predetermined distance; a mounted portion detachably mounted to the sensor main body in a manner of maintaining the distance between the actuator held by the holding portion and the sensor main body within the predetermined distance; a main body frame connecting the holding portion and the mounted portion and extending along a first direction; and a protrusion protruding and extending from the main body frame along a third direction perpendicular to the first direction and a second direction from the fixture toward the sensor main body in a mounted state where the fixture is mounted to the sensor main body.

An aspect of the present disclosure is an actuator with a fixture, the actuator with a fixture includes the fixture; and the actuator held by the holding portion of the fixture.

An aspect of the present disclosure is a detection switch, the detection switch includes the sensor main body; and the actuator with a fixture.

### Advantageous Effects of Invention

According to the present disclosure, erroneous detection of the detection switch can be restrained during the maintenance work performed inside the door to which the detection switch is mounted, and the maintenance work can be smoothly progressed.

### BRIEF DESCRIPTION OF DRAWINGS

FIG. 1 is a diagram illustrating a configuration example of a door-attached device;

FIG. 2 is a perspective view illustrating a configuration example of the door;

FIG. 3 is a block diagram illustrating a configuration example of a detection switch;

FIG. 4A is a perspective view of the detection switch as seen from a first direction;

FIG. 4B is a perspective view of the detection switch as seen from a second direction;

FIG. 5A is a front view illustrating a state where an actuator with a fixture is to be mounted to a sensor main body;

FIG. 5B is a front view illustrating a state after the actuator with a fixture is mounted to the sensor main body;

FIG. 6A is a perspective view illustrating a state where the detection switch in a third mounted state is mounted to a fixing frame;

FIG. 6B is a side view illustrating the state where the detection switch in the third mounted state is mounted to the fixing frame;

FIG. 7A is a perspective view illustrating a state where the detection switch in a first mounted state is mounted to the fixing frame;

FIG. 7B is a side view illustrating the state where the detection switch in the first mounted state is mounted to the fixing frame;

FIG. 8 is a side view illustrating a state where the detection switch in a second mounted state is mounted to the fixing frame;

FIG. 9 is a perspective view of one end of the sensor main body;

FIG. 10 is a perspective view of a first engaging portion at one end of a fixture;

FIG. 11 is a perspective view of the sensor main body and the first engaging portion in the first mounted state;

FIG. 12 is a perspective view of the other end of the sensor main body;

FIG. 13 is a perspective view of a second engaging portion at the other end of the fixture;

FIG. 14A is a perspective view of the sensor main body and the second engaging portion in the first mounted state;

FIG. 14B is a cross-sectional view obtained by cutting the sensor main body and the second engaging portion in the first mounted state along a plane passing through a first engaging convex portion and a second engaging convex portion and parallel to a Y2Z2 plane;

FIG. 15A is a perspective view of the sensor main body and the second engaging portion in the second mounted state;

FIG. 15B is a perspective view of the sensor main body and the second engaging portion in the second mounted state as seen from a direction different from that in FIG. 15A;

FIG. 16A is a perspective view of the sensor main body and the second engaging portion in the third mounted state;

FIG. 16B is a perspective view of the sensor main body and the second engaging portion in the third mounted state as seen from a direction different from that in FIG. 16A;

FIG. 16C is a cross-sectional view obtained by cutting the sensor main body and the second engaging portion in the third mounted state along a plane passing through the second engaging convex portion and parallel to an X2Y2 plane;

FIG. 17 is a view of the fixture including a protrusion as seen from a negative side of a Z2 axis;

FIG. 18 is a diagram illustrating an example of a direction in which the fixture is mounted to the sensor main body in the third mounted state, and the door is closed;

FIG. 19 is a diagram illustrating an example of a direction in which the fixture is mounted to the sensor main body in the second mounted state, and the door is closed; and

FIG. 20 is a diagram illustrating an example of a direction in which the fixture is mounted to the sensor main body in the first mounted state, and the door is closed.

### DESCRIPTION OF EMBODIMENTS

Hereinafter, an embodiment will be described in detail with reference to the drawings as appropriate. However, unnecessarily detailed description may be omitted. For example, a detailed description of already well-known matters and a redundant description of substantially the same configuration may be omitted. This is to avoid unnecessary redundancy of the following description and to facilitate understanding of a person skilled in the art. It should be noted that the accompanying drawings and the following description are provided for a person skilled in the art to fully understand the present disclosure, and are not intended to limit the subject matter described in the claims.

### (Circumstances Leading to Obtaining an Embodiment According to the Present Disclosure)

In a switch system having a plurality of detection switches provided in a door or the like, when the detection switch detects an opened state of the door, a device (an internal device) such as a machine tool disposed inside the door stops operating. The internal device may be maintained periodically or irregularly. During the maintenance, the door is opened, and a worker enters the inside of the door from the door to perform maintenance work on the internal device.

A switch system in the related art includes a plurality of detection switches and a programmable logic controller (PLC). The detection switch is provided nearby the door and detects the opening and closing of the door. The PLC controls an operation of the internal device. In this case, the PLC controls driving of the internal device according to an output (a detection result) of the detection switch. Specifically, when the detection switch detects that the door is closed, the PLC drives the internal device. On the other hand, when the detection switch detects that the door is opened, the PLC stops the driving of the internal device.

During the maintenance work, when the worker needs to frequently move between the inside of the door and the outside of the door, or inspect the internal device in an opened state of the door, the internal device may be inspected in the opened state of the door. In this case, since the detection switch detects that the door is opened, the PLC stops the driving of the internal device. Therefore, the worker cannot perform the maintenance work because the internal device is not driven.

In order to prevent the driving of the internal device from stopping in the opened state of the door, it is conceivable that the detection switch is always in an on state during the maintenance work. In this case, it is necessary to always bring a sensor main body and an actuator close to each other in advance. Therefore, it is conceivable that a maintenance-use actuator is prepared in addition to a normal actuator provided near the door. However, in this case, there is a possibility that the maintenance-use actuator, which is brought close, and the normal actuator provided in the door may enter a detection range of the sensor main body at the same time, and the sensor main body may make an erroneous determination regarding an operation based on these actuators to be performed, or may be indefinite. In this case, an operation mode is not accurately set, the detection accuracy of abnormality detection is reduced, and there is a possibility that the maintenance work becomes difficult due to erroneous stop of the driving of the internal device.

In the embodiment below, a fixture, an actuator with a fixture, and a detection switch are described, and by using the fixture, the actuator with a fixture, and the detection switch, erroneous detection of the detection switch can be restrained during the maintenance work performed inside the door to which the detection switch is mounted, and the maintenance work can be smoothly progressed.

### Embodiment

### <Configurations of Door-Attached Device and Switch System>

First, a door-attached device and a switch system provided in a scene where the maintenance-use actuator is used will be described.

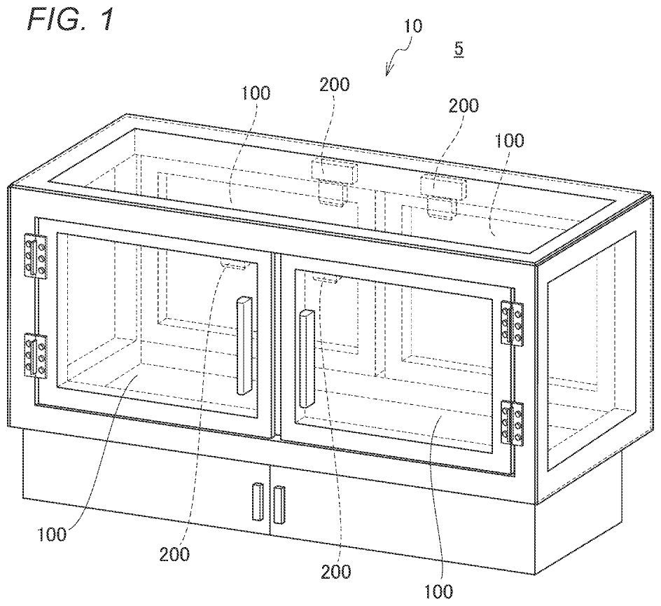

FIG. 1 is a diagram illustrating a configuration example of a door-attached device 10. The door-attached device 10 includes one or more doors 100 and one or more detection switches 200. The door 100 may widely include a door member related to the door such as a door portion, and may include a window. In addition, one or more devices (for example, a manufacturing device and other devices) are accommodated inside the door-attached device 10. The devices disposed inside the door-attached device 10 are also referred to as an “internal device”.

Further, a switch system 5 may be formed to include the plurality of detection switches 200. Further, the switch system 5 forms one group by the plurality of detection switches 200. At least one of the detection switches 200 is connected to the PLC.

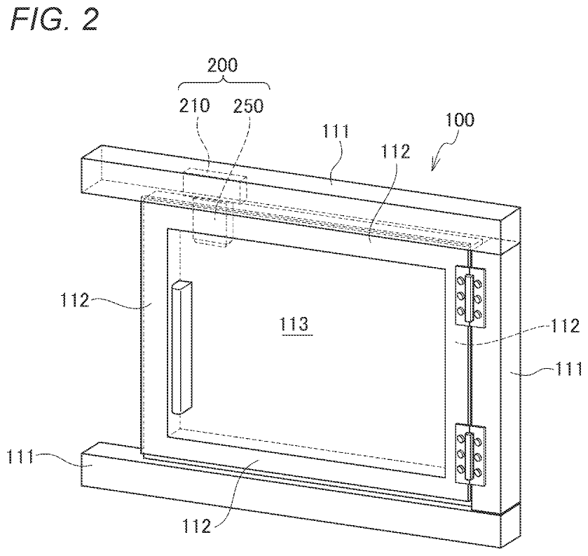

FIG. 2 is a perspective view illustrating a configuration example of the door 100. Each door 100 includes a fixing frame 111, a movable frame 112, and a door main body 113.

The fixing frame 111 may be a part of a member that covers the outer periphery of the door-attached device 10. The fixing frame 111 is, for example, an aluminum frame, and may be a frame formed of other materials. The fixing frame 111 does not have a light transmissive property.

The movable frame 112 is freely movable with respect to the fixing frame 111. As a result, the door 100 is freely openable and closable. The movable frame 112 is, for example, an aluminum frame, and may be a frame formed of other materials. The movable frame 112 does not have a light transmissive property.

The door main body 113 is surrounded by the movable frame 112 at the periphery of the door main body 113. The door main body 113 is formed of, for example, alight transmitting member. The light transmitting member may be formed of for example, transparent plastic or glass, and the same applies to the description of the following light transmitting member.

An opening and closing method of the door 100 may include a hinged door method, a sliding door method, a folding door method, a bellows method, a hinged double door method, a gull-wing method, a removable method, and the like.

The detection switch 200 functions as a door sensor that detects the opening and closing of the door 100. The detection switch 200 can detect the opening and closing of the door 100 (a main door) to which the detection switch 200 is mounted, and can also detect the opening and closing of the doors 100 (sub doors) other than the door to which the detection switch 200 is mounted. The detection switch 200 may have an interlock function, an external device monitoring (EDM) function, and the like.

The detection switch 200 includes a sensor main body 210 and an actuator 250. The sensor main body 210 is provided in the fixing frame 111 inside or outside the door-attached device 10. The actuator 250 is provided in the movable frame 112 inside or outside the door-attached device 10. Therefore, the detection switch 200 is positioned on a front surface side or a rear surface side of the fixing frame 111 and the movable frame 112 when seen by a checker who checks from the outside of the door-attached device 10. When the detection switch 200 is positioned on the front surface side, the checker can naturally check the display of the detection switch 200, and even when the detection switch 200 is positioned on the rear surface side, the checker can check the display of the detection switch 200 via the door main body 113 as a light transmitting member.

The sensor main body 210 may be provided in any direction with respect to the fixing frame 111 as long as opening and closing detection of the door 100 is possible. Specifically, with respect to the fixing frame 111, the sensor main body 210 may be provided from a side (that is, on a side surface of the fixing frame 111), may be provided from above (that is, on an upper surface of the fixing frame 111), and may be provided from below (that is, on a lower surface of the fixing frame 111).

The actuator 250 includes two types of actuators, namely, a normal actuator 250N and a maintenance-use actuator 250M. As illustrated in FIG. 2, the actuator 250 provided in the movable frame 112 is the normal actuator 250N. On the other hand, as described below, the maintenance-use actuator 250M is directly mounted to the sensor main body 210 by a fixture 300. The sensor main body 210 can be detected when either the normal actuator 250N or the maintenance-use actuator 250M is positioned in the detection range.

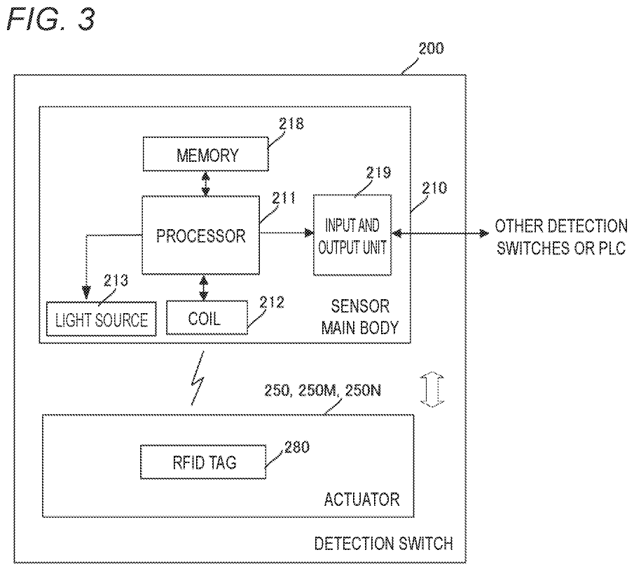

FIG. 3 is a block diagram illustrating a configuration example of the detection switch 200. The detection switch 200 includes the sensor main body 210 and the actuator 250 (a normal actuator 250N or a maintenance-use actuator 250M). The sensor main body 210 includes a processor 211, a coil 212, a light source 213, a memory 218, and an input and output unit 219. The actuator 250 includes a radio frequency identifier (RFID) tag 280.

The processor 211 achieves various functions in cooperation with the memory 218, that is, by executing programs stored in the memory 218. The processor 211 may include a micro processing unit (MPU), a central processing unit (CPU), a digital signal processor (DSP), and the like. The processor 211 controls the overall operation of the sensor main body 210.

The processor 211 detects whether the main door is closed (the closed state) or opened (the opened state) based on an approach state between the coil 212 of the sensor main body 210 and an RFID tag 280 of the actuator 250.

The processor 211 sets any operation mode among a plurality of operation modes of the detection switch 200. The operation mode includes a maintenance mode for the worker to perform maintenance and a normal mode other than the maintenance mode. In addition, the operation mode of the detection switch 200 may be set to other operation modes.

In the normal mode, when the detection switch 200 detects that the door 100 is closed, the PLC drives the internal device. On the other hand, when the detection switch 200 detects that the door 100 is opened, the PLC stops the driving of the internal device.

In addition, in the maintenance mode, the PLC invalidates the output of the detection switch 200. In this case, even when the detection switch 200 detects that the door 100 is opened, the PLC may not stop the driving of the internal device and perform at least a part of the driving (for example, driving of a portion requiring maintenance). Accordingly, even in the state where the door 100 is opened, the worker can perform the maintenance work when the internal device is driven.

The coil 212 receives power from the outside via the input and output unit 219, and transmits the power to an external device (for example, the actuator 250) by wireless power transmission. The wireless power transmission may be an electromagnetic induction method or a magnetic field resonance method. When receiving a predetermined signal from the external device, the coil 212 notifies the processor 211 of the reception of the predetermined signal. The external device is, for example, the actuator 250, and more specifically, the RFID tag 280 of the actuator 250. The coil 212 is disposed near a light projection port 214, for example.

For example, the coil 212 detects the closed state (an example of absence-of-abnormality) by receiving a predetermined signal from the normal actuator 250N, and detects the opened state (an example of presence-of-abnormality) by not receiving the predetermined signal. For example, the coil 212 detects a maintenance state (during the maintenance work) by receiving a predetermined signal from the maintenance-use actuator 250M.

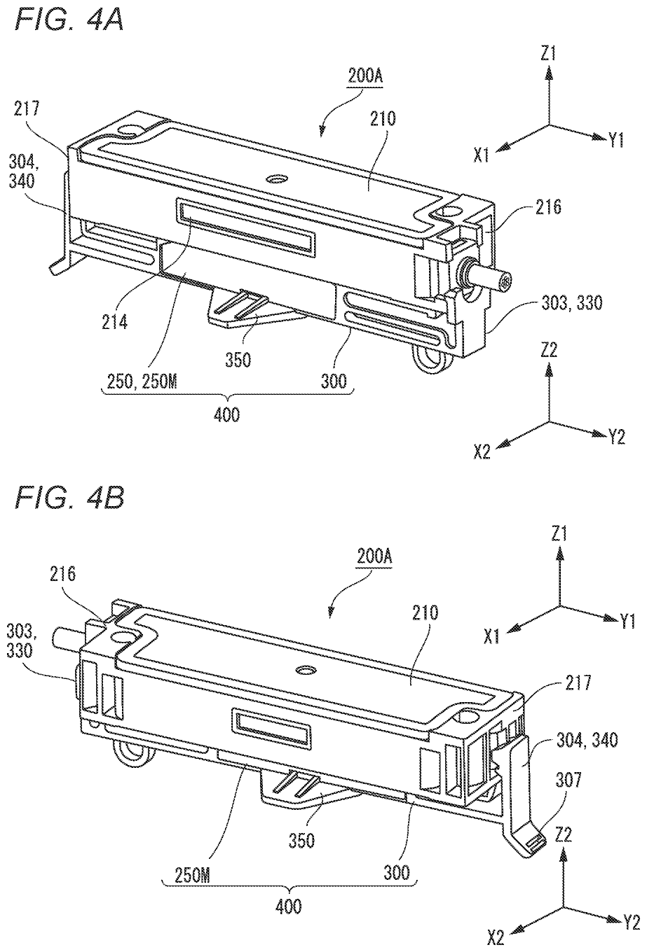

One or more light sources 213 may be provided. The light source 213 outputs light (displays) under the control of the processor 211. The light source 213 may project light to the actuator 250 through the light projection port 214 (see FIG. 4A to be described later) of the sensor main body 210 facing the actuator 250. The normal actuator 250N may receive the projected light, guide the light from the sensor main body 210 via a light guide portion formed of, for example, a light transmitting member, and output (emit) visible light. In addition, regarding the maintenance-use actuator 250M, as described below, the fixture 300 holding the maintenance-use actuator 250M may guide the light from the sensor main body 210, and output (emit) visible light. Further, the light source 213 may directly output (emit) the light to the outside of the detection switch 200 without projecting the light to the actuator 250. In any case, it is sufficient if the light emitted by the detection switch 200 can be checked from the outside of the door-attached device 10.

The light source 213 may display based on the operation mode of the detection switch 200 provided in the door 100 as a work target. The light source 213 may display based on a system operation mode defined by the operation modes of the detection switches 200 included in the switch system 5. For example, the light source 213 may display that there is an abnormality in the normal mode, may display that there is no abnormality in the normal mode, and may display that the maintenance work is being performed in the maintenance mode. The light source 213 can display in various display forms. The display form may be a display color, a display pattern (for example, turning-on, blinking, and turning-oil), light intensity, and the like.

The memory 218 includes a primary storage device (for example, a random access memory (RAM) or a read only memory (ROM)). The memory 218 may include other storage devices (for example, an SD card). The memory 218 stores various data, information, programs, and the like.

The memory 218 stores, for example, identification information (for example, an ED of the RFID tag 280) of the actuator 250. In this case, the memory 218 may store only the ID of the RFID tag 280 of the maintenance-use actuator 250M in advance, and may not store the ID of the RFID tag 280 of the normal actuator 250N.

The input and output unit 219 performs input and output of data, information, and a signal with the external device (for example, other switches, the PLC). Various signal lines are connected to the input and output unit 219. The input and output unit 219 performs input and output (at least one of the input and output) of signals such as a power supply signal, an abnormality detection signal, a mode notification signal, and a display control signal through the signal lines, for example. The input and output unit 219 may include various signal lines.

The power supply signal is a signal that includes power to be supplied to various electrical components included in the detection switch 200. The abnormality detection signal is a signal that indicates the presence or absence of the abnormality detected by the detection switch 200. The mode notification signal is a signal for notifying the operation mode set in the detection switch 200. The display control signal is a signal for controlling the display of the light source 213.

When the door 100 is in the closed state, the RFID tag 280 of the normal actuator 250N is disposed in a communicable range with the coil 212 of the sensor main body 210. For example, when the door 100 is in the closed state, the RFID tag 280 is disposed on a facing surface side facing the sensor main body 210 in the actuator 250. The RFID tag 280 transmits a predetermined signal. The RFID tag 280 is, for example, a passive tag, and operates by receiving the power supply from the outside (for example, the sensor main body 210). For example, the RFID tag 280 receives the power supply from the sensor main body 210 via the coil 212 and transmits the predetermined signal to the sensor main body 210. The predetermined signal may at least include information for identifying the RFID tag 280 (the ID of the RFID tag 280).

As described below, the RFID tag 280 of the maintenance-use actuator 250M can be disposed in the communicable range with the coil 212 of the sensor main body 210 by the fixture 300 independently of the opened and closed state of the door 100.

Here, a specific method for setting the operation mode of the detection switch 200 and an opening and closing detection method by the detection switch 200 will be described.

When the actuator 250 is disposed at a predetermined position with respect to the sensor main body 210, the sensor main body 210 detects the actuator 250. Specifically, when the RFID tag 280 of the actuator 250 is positioned in a range in which the wireless power transmission from the coil 212 of the sensor main body 210 is possible, the sensor main body 210 supplies power to die actuator 250, and the actuator 250 transmits the predetermined signal (the signal including the ID of the RFID tag 280) to the sensor main body 210. When the reception of the predetermined signal from the actuator 250 is detected, the coil 212 notifies the processor 211 of the ID of the RFID tag 280. When receiving the notification, the processor 211 recognizes the actuator 250.

When the ID of die RFID tag 280 notified from the coil 212 is included in the IDs of the one or more RFID tags 280 stored in the memo y 218, the processor 211 recognizes that the maintenance-use actuator 250M is detected. In this case, the processor 211 sets the operation mode of the detection switch 200 to the maintenance mode.

When the ID of the RFID tag 280 notified from the coil 212 is not included in the IDs of the one or more RFID tags 280 stored in the memory 218, the processor 211 recognizes that the normal actuator 250N is detected. In this case, the processor 211 sets the operation mode of the detection switch 200 to the normal mode.

In addition, when the sensor main body 210 detects the normal actuator 250N, the processor 211 determines that the movable frame 112 provided with the normal actuator 250N faces the fixing frame 111 provided with the sensor main body 210 in a predetermined state, and the door 100 is in the closed state. When the sensor main body 210 does not detect the normal actuator 250N, the processor 211 determines that the movable frame 112 provided with the normal actuator 250N does not face the fixing frame 111 provided with the sensor main body 210 in the predetermined state, and the door 100 is in the opened state.

Next, the internal device and the PLC will be described.

The devices (the internal device) inside the door-attached device 10 are, for example, a manufacturing device for manufacturing various products (for example, electric products, mechanical products, and chemical substances) and a device for assisting the manufacture. The internal device or the products are freely determined, and is, for example, an internal device or products whose handling should be noted. The operation of the internal device is controlled by the PLC.

The PLC is an example of the control device that controls the operation of the internal device. The PLC is connected between the detection switch 200 and the internal device. Although not particularly illustrated, the PLC includes a processor, a memory, an input and output unit, and the like. The processor achieves various functions in cooperation with the memory included in the PLC. The processor may include an MPU, a CPU, a DSP, and the like. The processor controls the overall operation of the PLC. The input and output unit performs input and output of data, information, and a signal with the external device (for example, the detection switch 200, the internal device). Various signal lines are connected to the input and output unit. The input and output unit can perform input and output (at least one of the input and output) of signals such as a power supply signal, an abnormality detection signal, a mode notification signal, a display control signal, a PLC control signal for controlling the PLC, and a device control signal for controlling the internal device via the signal lines, for example. The PLC may be included in the switch system 5.

### <Configurations of Maintenance-Use Actuator and Fixture>

FIGS. 4A and 4B are perspective views of a detection switch 200A according to the embodiment. FIG. 4A is a perspective view of the detection switch 200A as seen from a first direction. FIG. 4B is a perspective view of the detection switch 200A as seen from a second direction opposite to the first direction.

The detection switch 200A includes the sensor main body 210, the maintenance-use actuator 250M (also simply referred to as the actuator 250M), and the fixture 300. The configurations and functions of the sensor main body 210 and the actuator 250M may be the same as those of the sensor main body 210 and the actuator 250 described with reference to FIGS. 1 to 3. However, the actuator 250M is not provided in the movable frame 112, but is directly mounted to the sensor main body 210 via the fixture 300. The actuator 250M and the fixture 300 constitute an actuator with a fixture 400. The actuator with a fixture 400 can independently flow separately from the detection switch 200A, and can be carried by the worker.

The sensor main body 210 and the actuator 250M in the detection switch 200A are used in a state where a distance therebetween is maintained within a predetermined distance by the fixture 300. The fixture 300 serves to fix the actuator 250M to the sensor main body 210 based on a predetermined positional relation.

An X1 direction (a direction of an X1 axis), a Y1 direction (a direction of a Y1 axis), and a Z1 direction (a direction of a Z1 axis) of each coordinate in FIG. 4A and FIG. 4B correspond to a first thickness direction, a longitudinal direction, and a second thickness direction of the sensor main body 210, respectively. Also in the subsequent drawings, the orientation of the sensor main body 210 is indicated by using this coordinate.

An X2 direction (a direction of an X2 axis), an Y2 direction (a direction of an Y2 axis), and a Z2 direction (a direction of a Z2 axis) of each coordinate in FIG. 4A and FIG. 4B correspond to a first thickness direction, a longitudinal direction, and a second thickness direction of the fixture 300, respectively. Also in the subsequent drawings, the orientation of the fixture 300 is indicated by using the present coordinate.

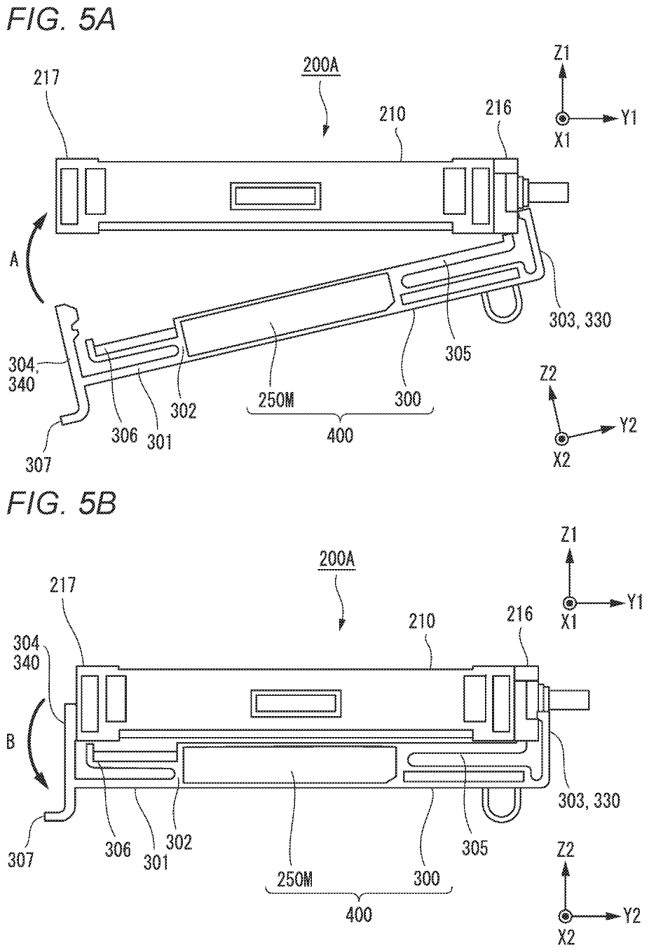

FIGS. 5A and 5B illustrate procedures for mounting the actuator with a fixture 400 to the sensor main body 210, and are views seen from the outside of the sensor main body 210 facing the light projection port 214 of the sensor main body 210. FIG. 5A is a front view illustrating a state where the actuator with a fixture 400 is to be mounted to the sensor main body 210. FIG. 5B is a front view illustrating a state after the actuator with a fixture 400 is mounted to the sensor main body 210.

The sensor main body 210 has a substantially rectangular parallelepiped shape having a longitudinal direction (the Y1 direction), and has one end 216 and the other end 217 in the longitudinal direction. Accordingly, the sensor main body 210 has a rectangular cross section parallel to a plane (an X1Z1 plane) orthogonal to the longitudinal direction thereof, and the rectangular cross section has four sides. The sensor main body 210 has the light projection port 214 that emits the light from the light source 213.

The actuator 250M has a substantially rectangular parallelepiped shape, and is mounted to the fixture 300.

The fixture 300 is an elongated member having a longitudinal direction (the Y2 direction). The fixture 300 mounts the actuator 250M to the sensor main body 210 of the detection switch 200A. The fixture 300 includes a main body frame 301, a holding portion 302, mounted portions 303 and 304, a first beans portion 305, a second beam portion 306, a projection 307, and a protrusion 350.

The main body frame 301 is a member that extends in the longitudinal direction of the fixture 300 and forms a main frame of the fixture 300. The holding portion 302 is provided at a substantially central position in the longitudinal direction of the fixture 300, that is, at a substantially central position of the main body frame 301, and holds the actuator 250M. The holding portion 302 is formed integrally with the main body frame 301, and may have a shape of a substantially rectangular annular member having a space at a center thereof. An outer shape of the actuator 250M is a shape substantially along an outer shape of the space. By fitting the actuator 250M into the space of the holding portion 302, the fixture 300 and the actuator 250M are integrated, and the actuator with a fixture 400 is constituted. The holding portion 302 can be engaged with and hold the actuator 250 by a snap-fit structure.

The mounted portions 303 and 304 are formed integrally with the main body frame 301, and extend in a direction (the Z2 direction) orthogonal to the longitudinal direction of the main body frame 301 at both ends of the main body frame 301. The mounted portions 303 and 304 are elastically deformable. Therefore, according to the procedures illustrated in FIGS. 5A and 5B, the worker can mount the actuator with a fixture 400 to the sensor main body 210 while deforming the mounted portions 303 and 304.

As illustrated in FIG. 5A, the worker first hooks and engages the mounted portion 303 provided at one end of the fixture 300 in the longitudinal direction with the one end 216 of the sensor main body 210 in the longitudinal direction. Thereafter, the worker rotates the fixture 300 (the actuator with a fixture 400) in a direction indicated by an arrow A, and brings the mounted portion 304 provided at the other end of the fixture 300 in the longitudinal direction close to the other end 217 of the sensor main body 210 in the longitudinal direction. Further, the worker presses toward an inner side (one end side of the fixture 300 in the longitudinal direction) while gripping the projection 307, and hooks and engages the mounted portion 304 with the other end 217 of the sensor main body 210 in the longitudinal direction while deforming the mounted portion 304 to expand outward. Then, the worker releases the pressing of the projection 307. According to the series of procedures, as illustrated in FIG. 5B, the actuator with a fixture 400 can be mounted to the sensor main body 210.

On the other hand, from the state of FIG. 5B, the worker presses toward the inner side while gripping the projection 307, and removes the mounted portion 304 from the other end 217 of the sensor main body 210 in the longitudinal direction while deforming the mounted portion 304 to expand outward. Then, the worker releases the pressing of the projection 307. Then, the worker can rotate the fixture 300 (the actuator with a fixture 400) in a direction indicated by an arrow B, which is a direction opposite to the direction indicated by the arrow A, and can remove the actuator with a fixture 400 from the sensor main body 210 as illustrated in FIG. 5A.

In addition, the worker may mount only the fixture 300 to the sensor main body 210 in a manner illustrated in FIGS. 5A and 5B in a state where the holding portion 302 does not hold the actuator 250M. Thereafter, the state in FIG. 5B is achieved by the worker fitting the actuator 250M into the holding portion 302.

The actuator 250M can communicate with the sensor main body 210 when a distance to the sensor main body 210 is within a predetermined distance (equal to or less than the predetermined distance), specifically, when the actuator 250M is positioned within a range in which communication by the coil 212 is possible. The holding portion 302 can hold the actuator 250M such that the distance to the sensor main body 210 is within the predetermined distance. Accordingly, the communication between the actuator 250M and the sensor main body 210 is maintained in a period in which the actuator with a fixture 400 is mounted to the sensor main body 210.

The mounted portions 303 and 304 are configured to be detachably mounted to the sensor main body 210 in a state where the distance between the actuator 250M held by the holding portion 302 and the sensor main body 210 is maintained within the predetermined distance. Specifically, the mounted portion 303 includes a first engaging portion 330 provided at the one end of the fixture 300 in the longitudinal direction and being engaged with the one end 216 of the sensor main body 210 in the longitudinal direction. Further, the mounted portion 304 includes a second engaging portion 340 provided at the other end of the fixture 300 in the longitudinal direction and being engaged with the other end 217 of the sensor main body 210 in the longitudinal direction. In addition, the first engaging portion 330 and the second engaging portion 340 are engaged with the one end 216 of the sensor main body 210 in the longitudinal direction and the other end 217 of the sensor main body 210 in the longitudinal direction by biasing forces in directions approaching each other, respectively. Therefore, the fixture 300 can be easily attached and detached with respect to the sensor main body 210 by the snap-fit structure.

Detailed configurations of the first engaging portion 330 and the second engaging portion 340 and a method of engaging with both ends of die sensor main body 210 will be described later. Further, details of the first beam portion 305, the second beam portion 306, the projection 307, and the protrusion 350 will be described later.

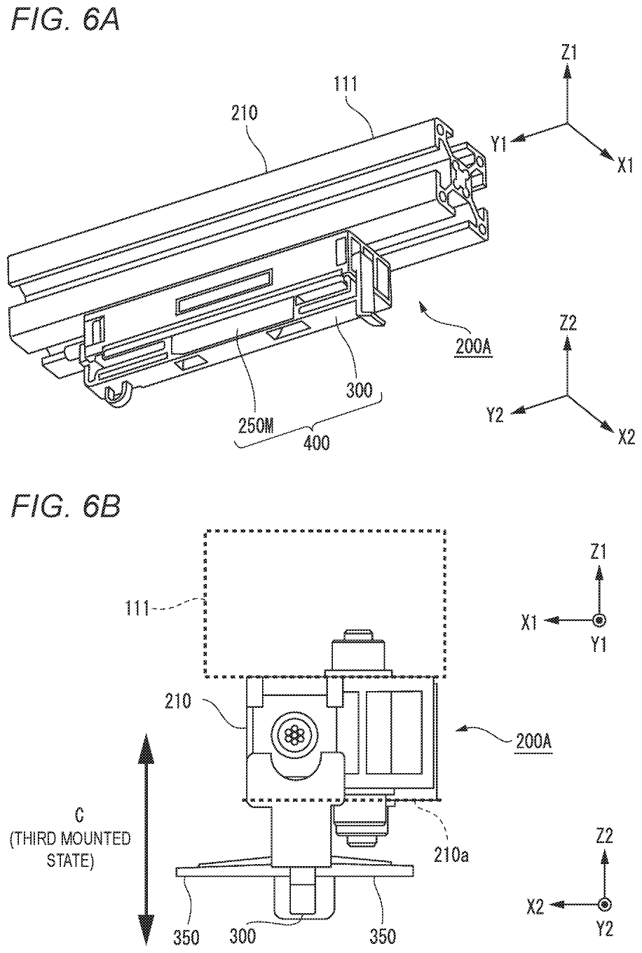

FIG. 6A is a perspective view illustrating a state where the detection switch 200A is mounted below the fixing frame 111. FIG. 6B is a side view in the same state as FIG. 6A. In FIGS. 6A and 6B, the detection switch 200A is provided on a lower surface of the fixing frame 111.

A scene where the detection switch 200A according to the present example is applied to the door-attached device 10 is assumed. In this scene, the sensor main body 210 is provided on the lower surface of the fixing frame 111 on an upper side of the door main body 113. The normal actuator 250N illustrated in FIGS. 1 and 2 may be provided iii the movable frame 112 as it is. In the present example, with respect to the sensor main body 210, the worker can mount the actuator 250M to the sensor main body 210 and can remove the actuator 250M from the sensor main body 210 in a direction indicated by an arrow C by using the fixture 300.

When the worker mounts the actuator 250M to the sensor main body 210, the detection switch 200A is always in an on state during a mounting period. The on state is a state where the actuator 250 (here, the actuator 250M) is detected by the sensor main body 210. Since the actuator 250M is detected, the sensor main body 210 sets the operation mode to the maintenance mode. Accordingly, even when the door 100 is in the opened state and the normal actuator 250N is separated from the sensor main body 210, the sensor main body 210 detects the actuator 250M and does not perform a determination of the presence-of-abnormality. In addition, in this case, the PLC continues at least a part of the driving of the internal device. Therefore, due to the presence of the detection switch 200A, the worker can perform the maintenance work while opening the door 100. Further, when the worker removes the actuator 250M from the sensor main body 210, the sensor main body 210 does not detect the actuator 250M, and thus the sensor main body 210 can shift the operation mode to the normal mode.

However, the sensor main body 210 may be provided in the fixing frame 111 in various forms. For example, the sensor main body 210 may be provided on the lower surface of the fixing frame 111 positioned on the upper side of the door main body 113, may be provided on a side surface of the fixing frame 111 positioned on the upper side or a lower side of the door main body 113, or may be provided on an upper surface of the fixing frame 111 positioned on the lower side of the door main body 113. In addition, since a providing form of the sensor main body 210 with respect to the fixing frame Ill changes, the orientation (a posture) of the sensor main body 210 with respect to the fixing frame 111 can also change.

In the example of FIGS. 6A and 6B, the worker can operate the fixture 300 in the direction indicated by the arrow C to mount and remove the actuator 250M with respect to the sensor main body 210. The above means that among surfaces corresponding to the four sides of the rectangular cross section of the sensor main body 210, the fixture 300 (the actuator with a fixture 400) is attachable and detachable with respect to a surface 210a (or a side 210a of the cross section) illustrated in FIG. 6B.

When it is assumed that only the surface 210a is attachable and detachable with respect to the fixture 300, a case may occur where the attaching and detaching of the fixture 300 may become difficult depending on a providing relation of the sensor main body 210 with respect to the fixing frame 111. The reason for the above is that depending on the providing relation described above, there is a possibility that the surface 210a faces a direction in which the worker is difficult to operate or in a direction in which the worker cannot operate. For example, when the sensor main body 210 is provided on the side surface of the fixing frame 111 on the upper side of the door main body 113, the surface 210a faces the outside of the fixing frame 111. In this case, the worker needs to bring the fixture 300 close from the outside, but mounting work of the fixture 300 is difficult when a position of the fixing frame 111 is high, and the mounting work of the fixture 300 cannot be performed when there is no empty space in the vicinity of the outside of the fixture 300. In such a case, the workability during maintenance may be insufficient.

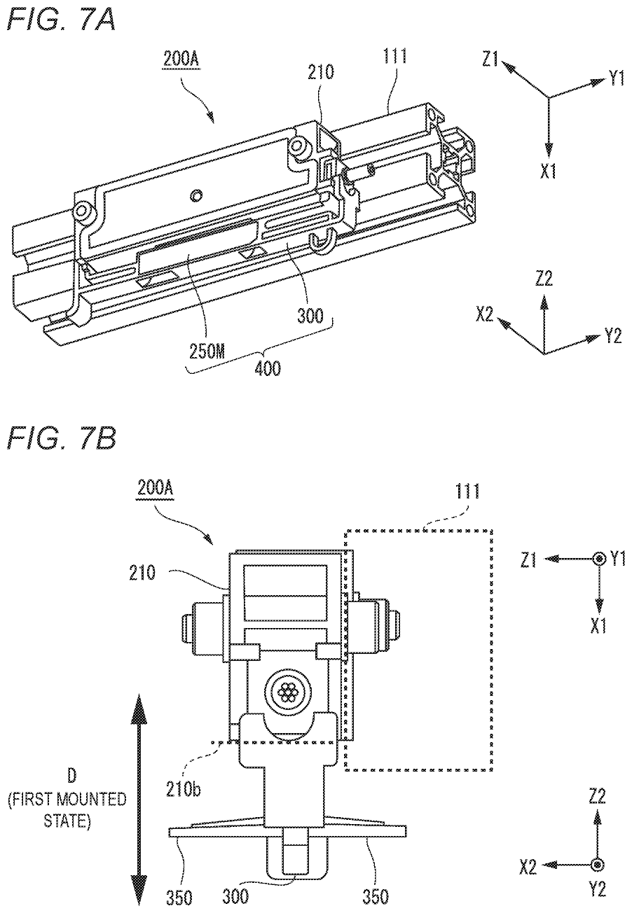

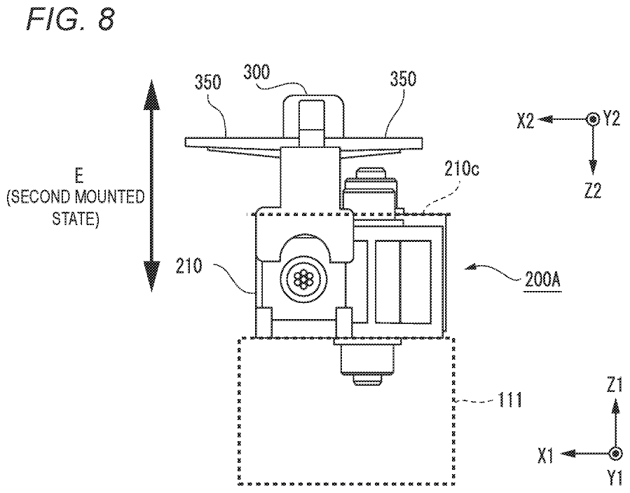

On the other hand, the fixture 300 may be mountable, via the mounted portions 303 and 304, from a direction facing any one of three sides which the normal actuator 250N approaches among the four sides of the rectangular cross section orthogonal to the longitudinal direction of the sensor main body 210. In this case, according to the form in FIGS. 7A and 7B and the form in FIG. 8 to be described later in addition to the form in FIGS. 6A and 6B, with respect to the sensor main body 210, the worker can mount the actuator 250M to the sensor main body 210 and can remove the actuator 250M from the sensor main body 210 by using the fixture 300.

FIGS. 7A and 7B illustrate an example in which the detection switch 200A is provided on the side surface of the fixing frame 111. In the example of FIGS. 7A and 7B, the worker can operate the fixture 300 in a direction indicated by an arrow D to remove the actuator 250M with respect to the sensor main body 210. The above means that among the surfaces corresponding to the four sides of the rectangular cross section along the X1Z1 plane of the sensor main body 210, the fixture 300 (the actuator with a fixture 400) is attachable and detachable with respect to a surface 210b (or a side 210b of the cross section) illustrated in FIG. 7B.

FIG. 8 illustrates an example in which the detection switch 200A is provided on the upper surface of the fixing frame ill. In the example of FIG. 8, the worker can operate the fixture 300 in a direction indicated by an arrow E to mount and remove the actuator 250M with respect to the sensor main body 210. The above means that among the surfaces corresponding to the four sides of the rectangular cross section along the X1Z1 plane of the sensor main body 210, the fixture 300 (the actuator with a fixture 400) is attachable and detachable with respect to a surface 210c (or a side 210c of the cross section) illustrated in FIG. 8.

As described above, the fixture 300 is configured to mount and remove the actuator 250M with respect to the sensor main body 210 from the three directions as illustrated in FIGS. 6A to 8. Here, the three directions are three directions, that is, the direction for the mounting and removing with respect to the surface 210b (FIGS. 7A and 7B), the direction for the mounting and removing with respect to the surface 210c (FIG. 8), and the direction for the mounting and removing with respect to the surface 210a (FIGS. 6A and 6B). Therefore, the worker can easily perform attaching and detaching work of the actuator 250M regardless of the providing form of the sensor main body 210 with respect to the fixing frame 111.

Further, in the sensor main body 210, the coil 212 is provided near the light projection port 214. Therefore, the mounting in the three directions described above is consistent with mounting from a direction corresponding to the light projection port 214 and mounting from both sides of the light projection port 214. When the fixture 300 is mounted in these three directions, the actuator 250M held by the holding portion 302 of the fixture 300 is positioned in a communication range of the coil 212, that is, the actuator 250M is positioned inside a detection range achieved by the sensor main body 210. When the fixture 300 is mounted to the sensor main body 210 from a side opposite to the light projection port 214, the actuator 250M held by the holding portion 302 of the fixture 300 is positioned outside the communication range of the coil 212, that is, the actuator 250M is positioned outside the detection range achieved by the sensor main body 210.

In the present embodiment, for convenience of description, a mounting method (an attaching and detaching method) illustrated in FIGS. 7A and 7B is referred to as a first mounting method (a first attaching and detaching method), and a mounted state of the fixture 300 (the actuator with a fixture 400) with respect to the sensor main body 210 achieved by this mounting method is referred to as a first mounted state. Similarly, a mounting method (an attaching and detaching method) illustrated in FIG. 8 is referred to as a second mounting method (a second attaching and detaching method), and a mounted state of the fixture 300 (the actuator with a fixture 400) with respect to the sensor main body 210 achieved by this mounting method is referred to as a second mounted state. Similarly, a mounting method (an attaching and detaching method) illustrated in FIGS. 6A and 6B is referred to as a third mounting method (a third attaching and detaching method), and a mounted state of the fixture 300 (the actuator with a fixture 400) with respect to the sensor main body 210 achieved by this mounting method is referred to as a third mounted state.

### <Specific Examples of Mounting Method and Mounted State of Fixture≥

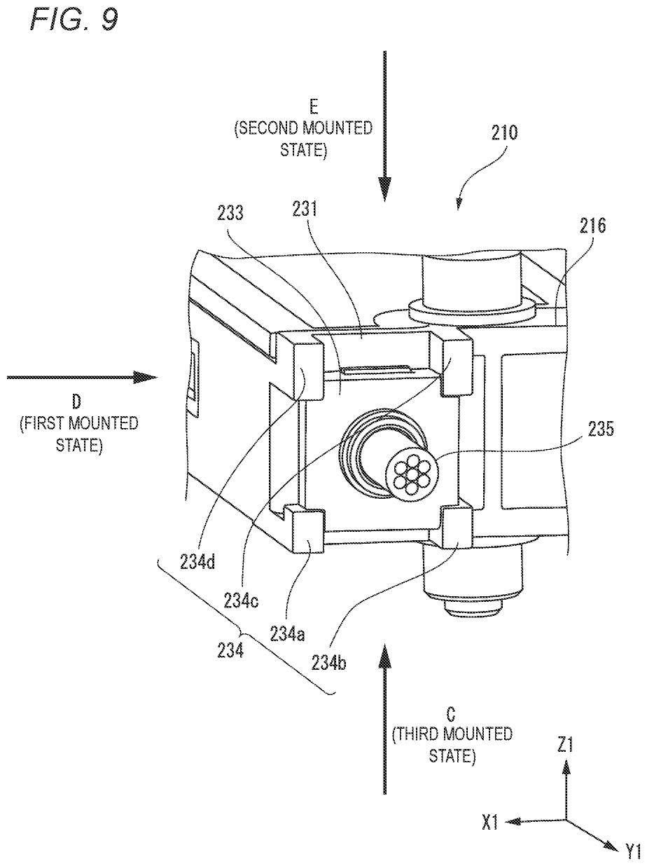

Next, specific configurations of the fixture 300 and the sensor main body 210 for achieving the mounting methods and the mounted states described above will be described with reference to FIGS. 9 to 11.

### <Engagement of Sensor Main Body and Fixture at One End Side>

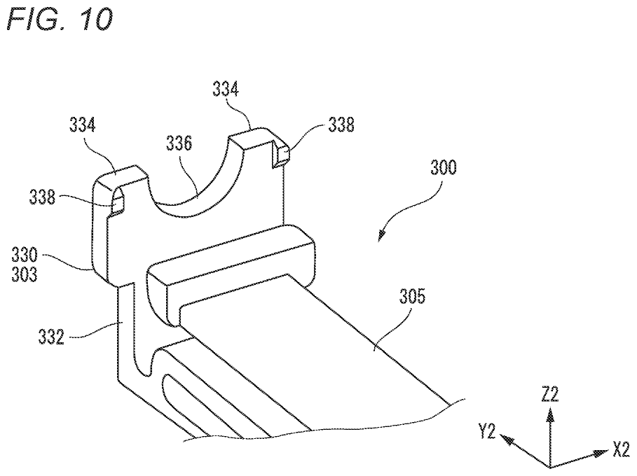

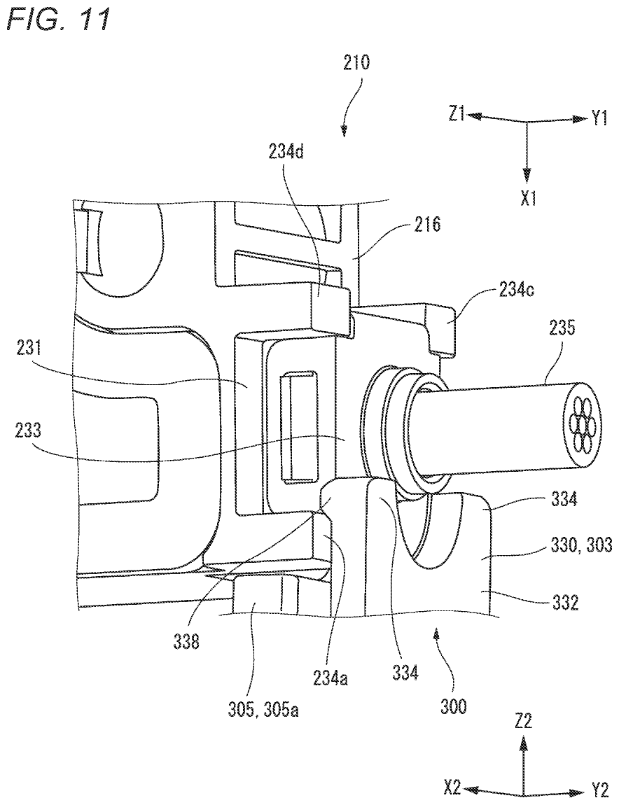

First, the engagement between the first engaging portion 330 in the mounted portion 303 of the fixture 300 and the one end 216 of the sensor main body 210 in the longitudinal direction will be described. FIG. 9 is a perspective view of the one end 216 of the sensor main body 210. FIG. 10 is a perspective view of the first engaging portion 330 at the one end of the fixture 300. FIG. 11 is a perspective view of the sensor main body 210 and the first engaging portion 330 in the first mounted state.

As illustrated in FIG. 9, a projecting portion 233 having a substantially square shape, which is close to a positive side in the X1 direction and projects in the longitudinal direction, is provided at the one end 216 of the sensor main body 210. Further, a connection cable 235 is drawn from a center of the projecting portion 233. Various kinds of wiring such as a power supply line and a signal line are stored in the connection cable 235.

At least one projection piece 234 (four in FIG. 9) is provided at one end surface 231, which is an end surface of the one end 216 of the sensor main body 210, so as to project along the longitudinal direction of the sensor main body 210. The projection pieces 234 are formed integrally with the end surface 231, and have an L shape to press corner portions (four corners in FIG. 9) of the projecting portion 233. Therefore, in FIG. 9, four projection pieces 234a, 234b, 234c, and 234d are arranged to correspond to vertices of the projecting portion 233 having a substantially square shape, and press the four corner portions of the projecting portion 233.

As illustrated in FIG. 10, the first engaging portion 330 includes a first engaging portion wall 332 extending along a plane (an X2Z2 plane) substantially orthogonal to the longitudinal direction of the fixture 300. The first engaging portion wall 332 has an elastic force, and expands outward in the longitudinal direction of the fixture 300 during the attaching and detaching of the fixture 300 (the actuator with a fixture 400). In the mounted state where the fixture 300 is mounted to the sensor main body 210, the first engaging portion wall 332 has an inward biasing force, that is, a biasing force toward the one end 216 of the sensor main body 210.

In addition, the first engaging portion wall 332 has, at a tip end thereof, two tip protrusions 334 with a semicircular arc-shaped surface 336 in a semicircular arc shape interposed therebetween. Further, the first engaging portion wall 332 has at least one locking piece 338 at the tip end thereof. The locking piece 338 projects toward a second engaging portion 340 side from a corner portion at the tip end of the first engaging portion wall 332, in particular, corner portions at tip ends of the tip protrusions 334 of the first engaging portion wall 332. In FIG. 10, the two locking pieces 338 project from the two corner portions at the tip ends of the two tip protrusions 334 toward the second engaging portion 340 side.

FIG. 11 illustrates the first mounted state of the sensor main body 210 and the first engaging portion 330. In the mounted state of the fixture 300 to the sensor main body 210, the first engaging portion 330 is engaged with the one end 216 of the sensor main body 210. In this case, the locking pieces 338 of the first engaging portion 330 are engaged with the projection pieces 234 at the one end 216 of the sensor main body 210 by the biasing force of the first engaging portion wall 332. In the present example, the two locking pieces 338 are engaged with any two of the four projection pieces 234a, 234b, 234c, and 234d. Specifically, when the locking pieces 338 press the projection pieces 234a and 234b toward the positive side in the X1 direction and sandwich an end portion of the projecting portion 233 on the positive side in the X1 direction from both sides in the Z1 direction, the first engaging portion 330 and the one end 236 of the sensor main body 210 are engaged with each other.

Here, the engagement of the sensor main body 210 and the first engaging portion 330 in the first mounted state is described, and the sensor main body 210 and the first engaging portion 330 are similarly engaged also in the second mounted state and the third mounted state. This is because the projecting portion 233 and the four projection pieces 234 are arranged in a substantially square shape, and thus even when the fixture 300 is mounted in any direction of the four sides of the square shape, the mounting can be achieved due to symmetry.

In the first mounted state of FIG. 11, the two locking pieces 338 are engaged with the two projection pieces 234a and 234b among the four projection pieces 234a, 234b, 234c, and 234d. Similarly, in the second mounted state illustrated in FIG. 8 and the like, the two locking pieces 338 are engaged with the two projection pieces 234a and 2344 among the four projection pieces 234a, 234b, 234c, and 234d. Similarly, hi the third mounted state illustrated in FIGS. 6A and 6B, the two locking pieces 338 are engaged with the two projection pieces 234b and 234c among the four projection pieces 234a, 234b, 234c, and 234d. In this way, the fixture 300 can be easily engaged with the one end 216 of the sensor main body 210 from the three directions by using the two locking pieces 338.

As described above, the fixture 300 is mountable, via the mounted portion 303, from the direction facing any one of the three sides among the four sides of the rectangular cross section (the cross section along the X1 Z1 plane) orthogonal to the longitudinal direction of the sensor main body 210. In this case, the two locking pieces 338 of the fixture 300 are engaged with the two projection pieces 234 among the four projection pieces 234a, 234b, 234c, and 234d from the directions facing the three sides among the four sides around the projecting portion 233 included in the end surface 231. Therefore, the fixture 300 and the sensor main body 210 can be reliably engaged with each other at the one end side.

The directions facing the three sides are a first mounting direction (for example, FIGS. 7A, 7B, and 11), a second mounting direction (for example, FIG. 8), and a third mounting direction (for example, FIGS. 6A and 6B). In FIG. 9, in order to achieve the mounted states corresponding to these mounting directions, the directions in which the fixture 300 approaches the sensor main body 210 are illustrated. Further, the arrow C, the arrow D, and the arrow E in FIG. 9 correspond to the arrows in FIGS. 6B, 7B, and 8, respectively.

### <Engagement of Sensor Main Body and Fixture at Other End Side>

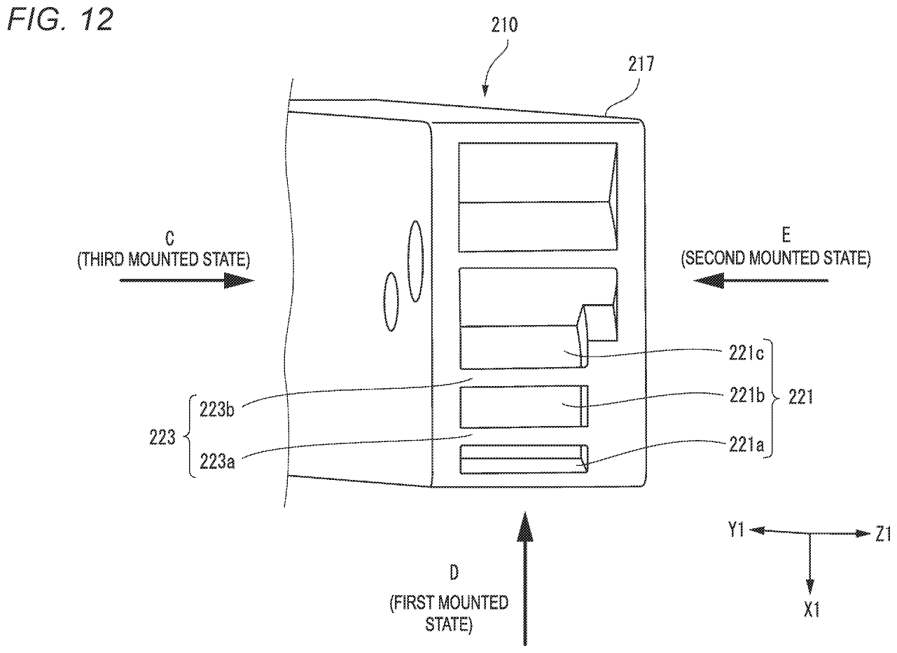

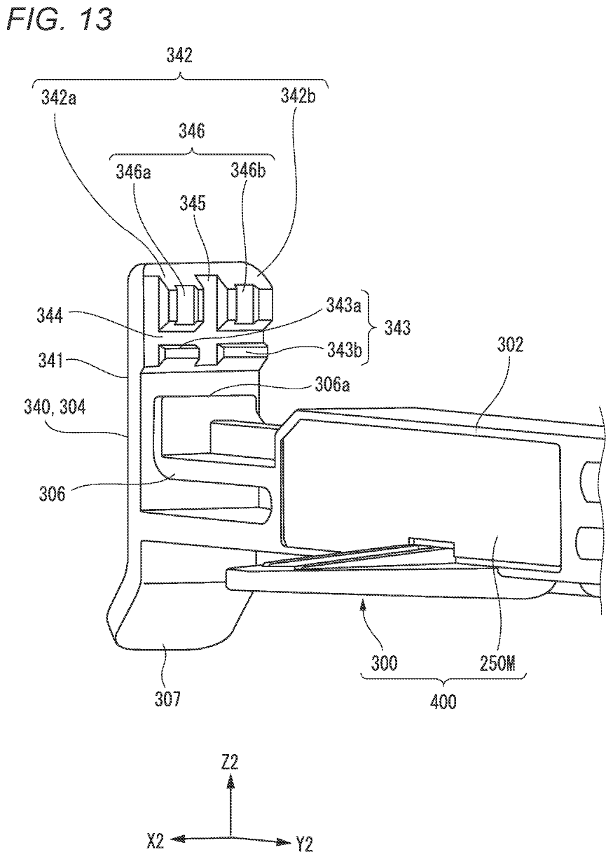

Next, the engagement between the second engaging portion 340 in the mounted portion 304 of the fixture 300 and the other end 217 of the sensor main body 210 in the longitudinal direction will be described with reference to FIGS. 12 to 16B. FIG. 12 is a perspective view of the other end 217 of the sensor main body 210. FIG. 13 is a perspective view of the second engaging portion 340 at the other end of the fixture 300.

As illustrated in FIG. 12, at least one recess portion 221 is provided at the other end 217 of the sensor main body 210 in the longitudinal direction. The recess portion 221 is recessed in the longitudinal direction of the sensor main body 210, and has a rectangular shape on the X1Z1 plane, for example. Further, in the present embodiment, the recess portion 221 is disposed via a linear ridge 223. Specifically, three recess portions 221a, 221b, and 221c are arranged in a state of being aligned in parallel to each other via a plurality of the ridges 223, via two ridges 223a and 223b in FIG. 12.

As illustrated in FIG. 13, the second engaging portion 340 includes a second engaging portion wall 341 extending along a plane tan X2Z2 plane) orthogonal to the longitudinal direction of the fixture 300, at least one first engaging convex portion 342, and at least one second engaging convex portion 343. The second engaging portion wall 341 has an elastic force, and expands outward in the longitudinal direction of the fixture 300 during the attaching and detaching of the fixture 300 (the actuator with a fixture 400). In the mounted state where the fixture 300 is mounted to the sensor main body 210, the second engaging portion wall 341 has an inward biasing force, that is, a biasing force toward the other end 217 of the sensor main body 210.

The first engaging convex portion 342 projects from the second engaging portion wall 341 toward a first engaging portion 330 side. The second engaging convex portion 343 projects from the second engaging portion wall 341 toward the first engaging portion 330 side. The first engaging convex portion 342 is disposed on a tip end side (a positive side of the Z2 direction) of the second engaging portion wall 341 by about a predetermined distance from the second engaging convex portion 343, specifically, by a linear first gap 344 having a predetermined width.

Further, the second engaging portion wall 341 includes a plurality of (two in FIG. 13) first engaging convex portions 342a and 342b via a second gap 345 orthogonal to the first gap 344. Similarly, the second engaging portion wall 341 includes a plurality of (two in FIG. 13) second engaging convex portions 343a and 343b via the second gap 345. Here, a row in which the first engaging convex portion 342a and the second engaging convex portion 343a are aligned is arranged with the second gap 345 from a row in which the first engaging convex portion 342b and the second engaging convex portion 343b are aligned. That is, on the second engaging portion wall 341, the row in which the first engaging convex portion 342a and the second engaging convex portion 343a are aligned and the row in which the first engaging convex portion 342b and the second engaging convex portion 343b are aligned are arranged to be parallel to each other via the second gap 345.

Further, each of the plurality of first engaging convex portions 342a and 342b has, at the top thereof, a recessed surface 346 recessed from a surface along the X2Z2 plane. As a result, the first engaging convex portion 342a has a recessed surface 346a, and the first engaging convex portion 342b has a recessed surface 346b. The recessed surface 346 is defined by a flat bottom surface having a rectangular shape.

### <Engagement at Other End Side in First Mounted State>

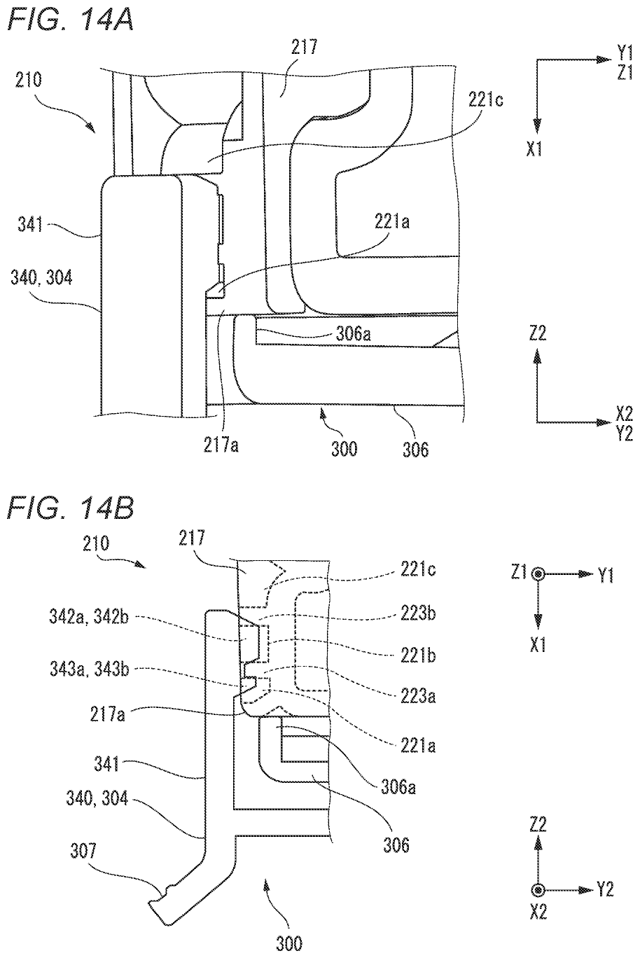

FIG. 14A is a perspective view of the other end 217 of the sensor main body 210 and the second engaging portion 340 of the fixture 300 in the first mounted state. FIG. 14B is a cross-sectional view obtained by cutting the other end 217 of the sensor main body 210 and the second engaging portion 340 of the fixture 300 in the first mounted state along a plane passing through the first engaging convex portion 342 and the second engaging convex portion 343 and parallel to a Y2Z2 plane. FIG. 14B illustrates a negative side of the X2 axis with respect to the plane (a cross section) passing through the first engaging convex portion 342 and the second engaging convex portion 343 and parallel to the Y2Z2 plane.

In the first mounted state, the two first engaging convex portions 342a and 342b are engaged with the recess portion 221b by the biasing force of the second engaging portion wall 341. The two first engaging convex portions 342a and 342b are aligned along the X2 direction as illustrated in FIG. 13, and can be engaged with the recess portion 221b extending along the Z1 direction illustrated in FIG. 12.

Further, the first gap 344 is engaged with the ridge 223a by the biasing force of the second engaging portion wall 341. The first gap 344 extends linearly along the X2 direction as illustrated in FIG. 13, and can be engaged with the ridge 223a extending along the Z1 direction illustrated in FIG. 12.

Further, as illustrated in FIGS. 13 and 14B, the first engaging convex portions 342a and 342b have a tapered shape in which a pair of end surfaces (both end surfaces in the Z2 direction) facing each other approach each other toward the top. Accordingly, the first engaging convex portions 342a and 342b can smoothly enter the recess portion 221b at the time of engagement, and the smooth engagement is ensured. Further, as illustrated in FIGS. 13 and 14B, the second engaging convex portions 343a and 343b have a tapered shape in which an end surface on a negative side in the Z2 direction is inclined to a positive side in the Z2 direction toward the top. Accordingly the second engaging convex portions 343a and 343b can smoothly enter the recess portion 221a at the time of engagement, and the smooth engagement is ensured.

In this manner, even in the first mounted state, the fixture 300 and the sensor main body 210 can be reliably engaged with each other at the other end side. Further, both end surfaces of the recess portions 221a and 221b in the Z1 direction exist on both outer sides of the first engaging convex portions 342a and 342b and the second engaging convex portions 343a and 343b in the X2 direction, that is, the Z1 direction, respectively. These end surfaces can restrict the movement of the first engaging convex portions 342a and 342b and the second engaging convex portions 343a and 343b toward the X2 direction, that is, the Z1 direction.

### <Engagement at Other End Side in Second Mounted State>

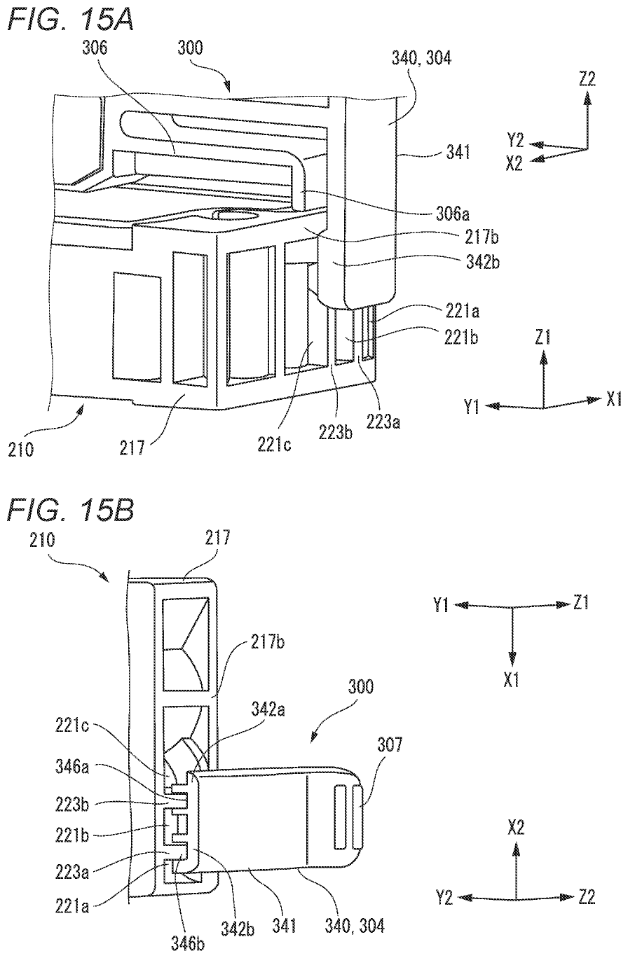

FIG. 15A illustrates a perspective view of the other end 217 of the sensor main body 210 and the second engaging portion 340 of the fixture 300 in the second mounted state. FIG. 15B is a perspective view of the other end 217 of the sensor main body 210 and the second engaging portion 340 of the fixture 300 in the second mounted state as seen from a direction different from that in FIG. 15A.

In the second mounted state, the recessed surfaces 346a and 346b of the two first engaging convex portions 342a and 342b are engaged with the two ridges 223a and 223b by the biasing force of the second engaging portion wall 341, respectively. The two recessed surfaces 346a and 346b extend to form a rectangular shape along the Z2 direction as illustrated in FIG. 13, and can be engaged with the two ridges 223a and 223b extending along the Z1 direction illustrated in FIG. 12.

In addition, as illustrated in FIG. 12, recessed parts of the recess portions 221a and 221 b and the recess portion 221c on the positive side in the X1 direction are closer to the negative side in the Z1 direction, and the other end surface, which is an end surface of the other end 217, is on the positive side in the Z1 direction. Therefore, in the second mounted state, the two second engaging convex portions 343a and 343b move onto the other end surface and are not engaged with the recess portion 221 and the ridge 223 of the sensor main body 210.

In this manner, even in the second mounted state, the fixture 300 and the sensor main body 210 can be reliably engaged with each other at the other end side. Further, since the recessed surfaces 346a and 346b of the first engaging convex portions 342a and 342b are engaged with the ridges 223a and 223b, the movement of the actuator 250M in the X1 direction, that is, the X2 direction with respect to the sensor main body 210 can be restricted.

### <Engagement at Other End Side in Third Mounted State>

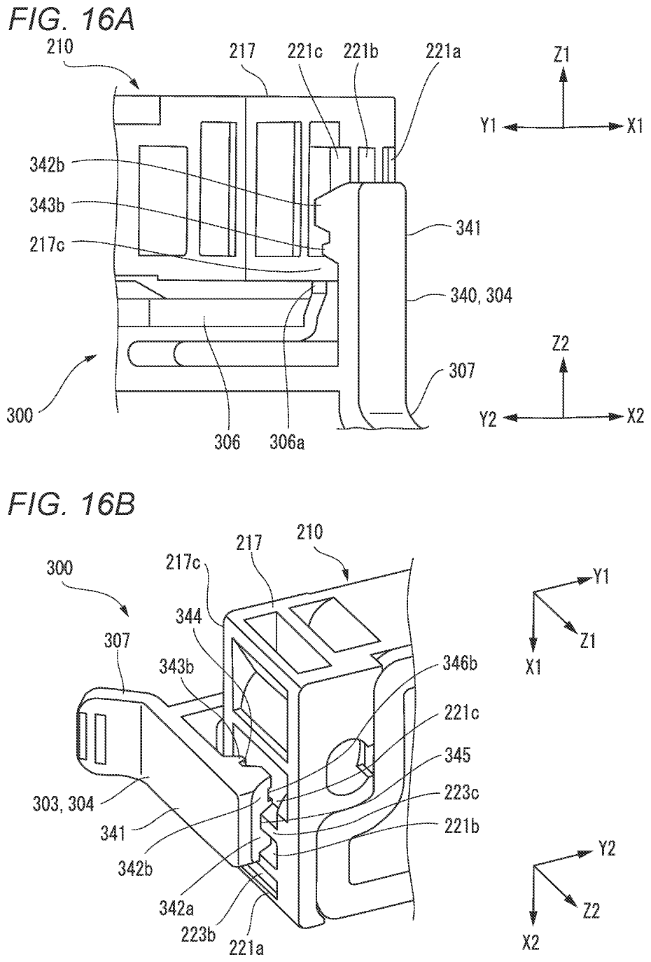

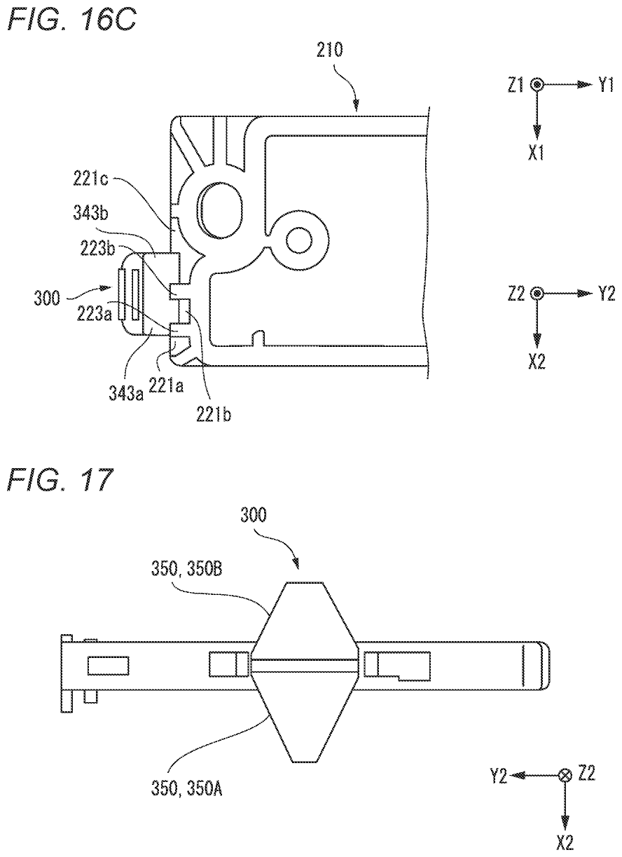

FIG. 16A is a perspective view of the other end 217 of the sensor main body 210 and the second engaging portion 340 of the fixture 300 in the third mounted state. FIG. 16B is a perspective view of the other end 217 of the sensor main body 210 and the second engaging portion 340 of the fixture 300 in the third mounted state as seen from a direction different from that in FIG. 16A. FIG. 16C is a cross-sectional view obtained by cutting the other end 217 of the sensor main body 210 and the second engaging portion 340 of the fixture 300 in the third mounted state along a plane passing through the second engaging convex portion 343 and parallel to an X2Y2 plane. FIG. 16C illustrates the negative side of the Z2 axis with respect to the plane (a cross section) passing through the second engaging convex portion 343 and parallel to the X2Y2 plane.

In the third mounted state, the second gap 345 is engaged with the ridge 223b by the biasing force of the second engaging portion wall 341. The second gap 345 extends linearly along the Z2 direction as illustrated in FIG. 13, and can be engaged with the ridge 223b extending along the Z1 direction illustrated in FIG. 12. In this case, the two first engaging convex portions 342a and 342b enter spaces of the two recess portions 221b and 221c, respectively. In addition, the two second engaging convex portions 343a and 343b enter the spaces of the two recess portions 221b and 221c, respectively.

In this manner, even in the third mounted state, the fixture 300 and the sensor main body 210 can be reliably engaged with each other at the other end side. Further, since the second gap 345 is engaged with the ridge 223b, the movement of the actuator 250M in the X1 direction, that is, the X2 direction with respect to the sensor main body 210 can be restricted.

As described above, the fixture 300 is configured to be mounted to the sensor main body 210, via the mounted portion 304, from the direction facing any one of the three sides among the four sides of the rectangular cross section (the cross section along the X1Z1 plane) orthogonal to the longitudinal direction of the sensor main body 210. In this case, at least one of the first engaging convex portion 342, the second engaging convex portion 343, the first gap 344, and the second gap 345 in the second engaging portion 340 (an example of a corrugated surface of the second engaging portion 340) of the mounted portion 304 of the fixture 300 is engaged with at least one of the recess portion 221a, the ridge 223a, the recess portion 221b, the ridge 223b, and the recess portion 221c of the sensor main body 210 (an example of a corrugated surface of the other end 217 of the sensor main body 210). Therefore, the fixture 300 can change an engagement method by changing a combination of the recess portion 221, the ridge 223, the engaging convex portions, the gaps, the recessed surface, and the like depending on the mounting direction (for example, the three directions described above) of the fixture 300 with respect to the sensor main body 210. Accordingly, the fixture 300 and the sensor main body 210 can be reliably engaged with each other at the other end side.

The directions facing the three sides are the first mounting direction, the second mounting direction, and the third mounting direction described above. In FIG. 12, in order to achieve the mounted states corresponding to these mounting directions, the directions in which the fixture 300 approaches the sensor main body 210 are illustrated. Further, the arrow C, the arrow D, and the arrow E in FIG. 12 correspond to the arrows in FIGS. 6B, 7B, and 8, respectively.

### ≤Configuration of Beam Portion

Next, the first beam portion 305 and the second beam portion 306 will be described.

The fixture 300 includes the first beam portion 305 that extends from the holding portion 302 toward the one end 216 of the sensor main body 210 in the longitudinal direction and has an open end 305a whose tip end is opened. In addition, the fixture 300 includes the second beam portion 306 that extends from the holding portion 302 toward the other end 217 of the sensor main body 210 in the longitudinal direction and has an open end 306a whose tip end is opened.

The first beam portion 305 is a beam-like member extending from a holding portion 302 side of a base toward the first engaging portion 330, and has an elastic force. That is, the first beam portion 305 has a biasing force toward the one end 216 of the sensor main body 210, and when the fixture 300 (the actuator with a fixture 400) is mounted to the sensor main body 210, the first beam portion 305 and the first engaging portion 330 sandwich the one end 216 of the sensor main body 210 in the longitudinal direction.

The second beam portion 306 is a beam-like member extending from the holding portion 302 side of the base toward the second engaging portion 340, and has an elastic force. That is, the second beam portion 306 has a biasing force toward the other end 217 of the sensor main body 210, and when the fixture 300 (the actuator with a fixture 400) is mounted to the sensor main body 210, the second beam portion 306 and the second engaging portion 340 sandwich the other end 217 of the sensor main body 210 in the longitudinal direction.

The first beam portion 305 cooperates with the first engaging portion 330 to sandwich the one end 216 of the sensor main body 210 in the longitudinal direction. The second beam portion 306 cooperates with the second engaging portion 340 to sandwich the other end 217 of the sensor main body 210 in the longitudinal direction. Therefore, the fixture 300 (the actuator with a fixture 400) is more reliably and stably fixed to the sensor main body 210.

Specifically, in the first mounted state, as illustrated in FIG. 11, the first beam portion 305 presses the one end 216 of the sensor main body 210 toward a negative side in the X1 direction by the biasing force. Further, the open end 305a of the first beam portion 305 and the locking piece 338 sandwich the one end 216 of the sensor main body 210 in the longitudinal direction, more specifically, the projection piece 234. Similarly, in the second mounted state and the third mounted state, the open end 305a of the first beam portion 305 and the locking piece 338 sandwich the one end 216 of the sensor main body 210 in the longitudinal direction, more specifically, the projection piece 234. Therefore, the fixture 300 (the actuator with a fixture 400) is more reliably and stably fixed to the sensor main body 210.

In addition, in the first mounted state, as illustrated in FIGS. 14A and 14B, the second beam portion 306 presses the other end 217 of the sensor main body 210 toward the negative side in the X1 direction by the biasing force. Further, the open end 306a of the second beam portion 306 and the first engaging convex portions 342a and 342b and the second engaging convex portions 343a and 343b sandwich the other end 217 of the sensor main body 210 in the longitudinal direction, more specifically, a side 217a of the other end 217. Therefore, the fixture 300 (the actuator with a fixture 400) is more reliably and stably fixed to the sensor main body 210.

In addition, in the second mounted state, as illustrated in FIGS. 15A and 15B, the second beam portion 306 presses the other end 217 of the sensor main body 210 toward the negative side in the Z1 direction by the biasing force. Further, the open end 306a of the second beam portion 306 and the first engaging convex portions 342a and 342b sandwich the other end 217 of the sensor main body 210 in the longitudinal direction, more specifically, a side 217b of the other end 217. Therefore, the fixture 300 (the actuator with a fixture 400) is more reliably and stably fixed to the sensor main body 210.

In addition, in the third mounted state, specifically, as illustrated in FIGS. 16A and 16B, the second beam portion 306 presses the other end 217 of the sensor main body 210 toward the positive side in the Z1 direction by the biasing force. Further, the open end 306a of the second beam portion 306 and the second engaging convex portions 343a and 343b sandwich the other end 217 of the sensor main body 210 in the longitudinal direction, more specifically, a side 217c of the other end 217. Therefore, the fixture 300 (the actuator with a fixture 400) is more reliably and stably fixed to the sensor main body 210.

As described above, in the mounted state of the fixture 300 to the sensor main body 210, the two open ends 305a and 306a come into contact with the one end 216 and the other end 217 facing the open ends 305a and 306a of the sensor main body 210, and bias from the fixture 300 toward the sensor main body 210, respectively. Further, the first engaging portion 330 and the second engaging portion 340 bias from the fixture 300 toward the sensor main body 210. Therefore, the fixture 300 can restrict the movement with respect to the sensor main body 210 in an arrangement direction of the fixture 300 and the sensor main body 210, and can be stably mounted to the sensor main body 210.

### <Configuration of Projection>

Next, the projection 307 will be described.

The fixture 300 includes the projection 307 extending in a direction opposite to the second engaging portion wall 341 of the second engaging portion 340. The projection 307 is configured to be gripped by the worker's hand or the like. By applying an external force to the projection 307 by using the hand or the like, the second engaging portion wall 341 can be moved (deformed). The worker can use the projection 307 in the attaching and detaching operation of the fixture 300 illustrated in FIGS. 5A and 5B. The worker can easily perform the mounting and removing of the fixture 300 having, for example, the snap-fit structure due to the presence of the projection 307.

### <Configuration of Protrusion>

Next, the protrusion 350 will be described.

FIG. 17 is a view of the fixture 300 including the protrusion 350 as seen from the negative side of the Z2 axis.

The fixture 300 includes at least one protrusion 350. The protrusion 350 extends along the first thickness direction (the X2 direction) perpendicular to the longitudinal direction (the Y2 direction) of the fixture 300. In addition, the protrusion 350 projects from the main body frame 301 in the X2 direction, and has a shape such as a wing. In FIG. 17, two protrusions 350 are provided, and a first protrusion 350A and a second protrusion 350B are included. The length of the first protrusion 350A along the X2 direction is longer than the length of the second protrusion 350B along the X2 direction. The two protrusions 350 respectively extend from the vicinity of a center portion of the main body frame 301 in the X2 direction and the Y2 direction to a positive direction and a negative direction of the X2 direction. Further, the protrusion 350 is made of, for example, a material having rigidity. The length (a dimension) of the first protrusion 350A along the X2 direction and the length (a dimension) of the second protrusion 350B along the X2 direction may be subjected to dimensional adjustment such that the normal actuator 250N provided in the door 100 to be described later does not enter the detection range for the actuator 250M achieved by the sensor main body 210, for example.

Since the fixture 300 includes the protrusion 350, even when the door 100 is going to be closed from the positive direction of the X2 direction, it is possible to prevent the door 100 from coming into contact with the protrusion 350 and coining closer to an actuator 250M side than a tip end of the protrusion 350. Therefore, it is possible to restrain the normal actuator 250N provided in the movable frame 112 on a door main body 113 side from entering the detection range (the communication range of the coil 212) for detecting the actuator 250 achieved by the sensor main body 210 provided in the fixing frame 111. Accordingly, it is possible to restrain both the maintenance-use actuator 250M and the normal actuator 250N from entering the detection range for the actuator 250 achieved by the sensor main body 210.

In addition, in FIG. 17, the protrusion 350 has a substantially trapezoidal shape in a plan view (with the X2Y2 plane as a cross section). An edge of the tip end of the protrusion 350 and an edge of a base end of the protrusion 350 are disposed in parallel. The protrusion 350 has a substantially trapezoidal shape that increases in diameter from the tip end toward the base end of the protrusion 350. That is, in the protrusion 350, the length of the edge of the base end on a main body frame 301 side is longer than the length of the edge of the tip end located at a position separated from the main body frame 301. Since the protrusion 350 has the substantially trapezoidal shape in this way, even when the fixture 300 is accommodated in an accommodation portion (a pocket and the like) at the time of carrying, it is possible to restrain the fixture 300 from being caught by the accommodation portion. The shape of the protrusion 350 is not limited to the substantially trapezoidal shape, and for example, the protrusion 350 may have a rectangular shape in the same plan view, may have a semicircular shape, or may have other shapes.

Further, the protrusion 350 is not limited to extending from the vicinity of the center portion of the main body frame 301, and for example, the protrusion 350 may be provided to extend in the X2 direction from at least one end portion (an end portion in the Y2 direction). Although it is illustrated that the number of the protrusions 350 is two, the member thereof is not limited thereto, and may be one, or three or more. The approach of the door 100 (that is, the approach of the normal actuator 250N) from at least one side in the X2 direction may be prevented by one or three or more protrusions 350. That is, the shape and the number of the protrusions 350 are not limited, and it is sufficient if the approach of the normal actuator 250N is inhibited such that any actuator 250 is detected by the sensor main body 210.

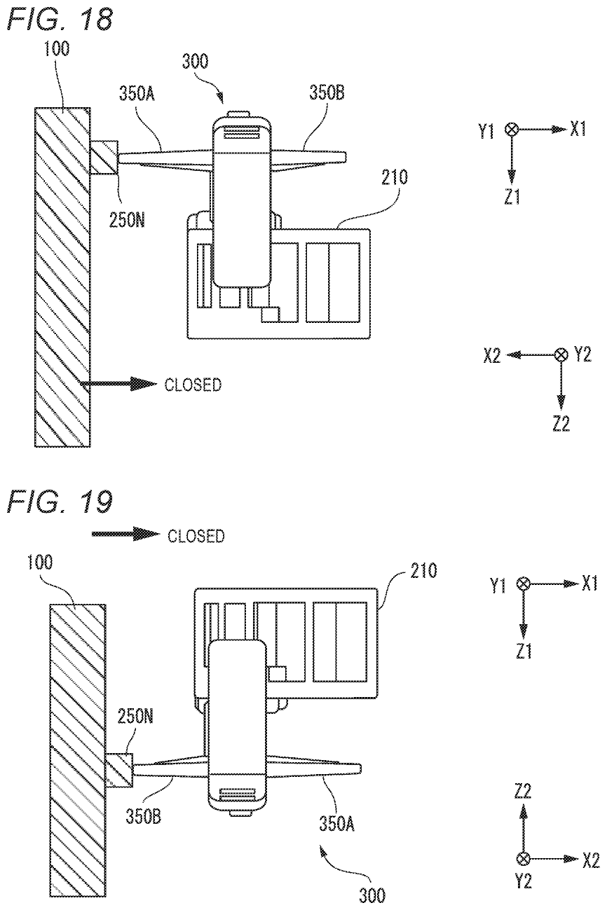

FIG. 18 is a diagram illustrating an example of a direction in which the fixture 300 is mounted to the sensor main body 210 in the third mounted state, and the door 100 is closed. In FIG. 18, the normal actuator 250N is provided iii the movable frame 112 of the door 100. The actuator 250N is provided closer to the sensor main body 210 than the door 100. Here, of the two protrusions 350, the first protrusion 350A is positioned on a door 100 side. In FIG. 18, although the length of the first protrusion 350A in the X2 direction is longer than that of the second protrusion 350B, the fixture 300 is disposed closer to the negative side in the X1 direction (the door 100 side) than a central position in the X1 direction with respect to the sensor main body 210, and thus the first protrusion 350A can come into contact with the door 100 and the normal actuator 250N.

Even when the door 100 is going to be closed in a close direction indicated by an arrow, the first protrusion 350A of the protrusion 350 comes into contact with the door 100 and the normal actuator 250N, and it is possible to prevent the normal actuator 250N from coming closer to the main body frame 301 than a tip end position of the first protrusion 350A. Accordingly, the first protrusion 350A can maintain a state where a distance between the normal actuator 250N and the sensor main body 210 is longer than a detectable distance. Accordingly, the maintenance-use actuator 250M is detected, the maintenance mode is maintained, the driving of the internal device is maintained, and the display indicating that the maintenance work is being performed can be continued.

FIG. 19 is a diagram illustrating an example of a direction in which the fixture 300 is mounted to the sensor main body 210 in the second mounted state, and the door 100 is closed. In FIG. 19, the normal actuator 250N is provided in the movable frame 112 of the door 100. The actuator 250N is provided closer to the sensor main body 210 than the door 100. Here, of the two protrusions 350, the second protrusion 350B is positioned on the door 100 side. In FIG. 19, although the length of the second protrusion 350B in the X2 direction is shorter than that of the first protrusion 350A, the fixture 300 is disposed closer to the negative side in the X1 direction (the door 100 side) than the central position in the X1 direction with respect to the sensor main body 210, and thus the second protrusion 350B can come into contact with the door 100 and the normal actuator 250N.

Even when the door 100 is going to be closed in a close direction indicated by an arrow, the second protrusion 350B of the protrusion 350 comes into contact with the door 100 and the normal actuator 250N, and it is possible to prevent the normal actuator 250N from coming closer to the main body frame 301 than a tip end position of the second protrusion 350B. Accordingly, the second protrusion 350B can maintain the state where the distance between the normal actuator 250N and the sensor main body 210 is longer than the detectable distance. Accordingly, the maintenance-use actuator 250M is detected, the maintenance mode is maintained, the driving of the internal device is maintained, and the display indicating that the maintenance work is being performed can be continued.

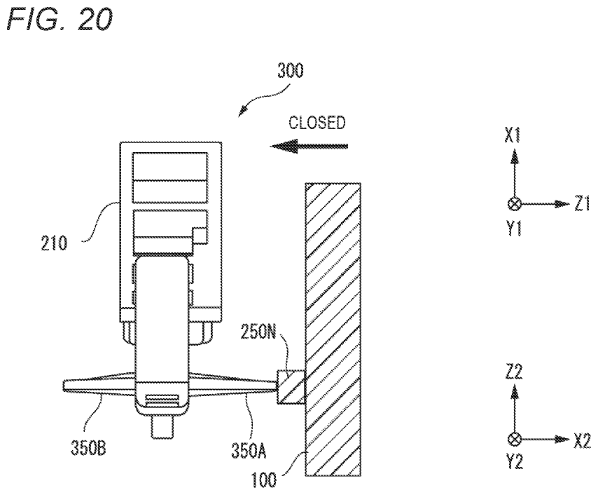

FIG. 20 is a diagram illustrating an example of a direction in which the fixture 300 is mounted to the sensor main body 210 in the first mounted state, and the door 100 is closed. In FIG. 20, the normal actuator 250N is provided in the movable frame 112 of the door 100. The actuator 250N is provided closer to the sensor main body 210 than the door 100. Here, of the two protrusions 350, the first protrusion 350A is positioned on a door 100 side. In FIG. 20, although the length of the first protrusion 350A in the X2 direction is longer than that of the second protrusion 350B, and the fixture 300 is disposed near the center of the Z1 direction (accurately, slightly closer to the negative side (a side opposite to the door 100) than the center of the Z1 direction) with respect to the sensor main body 210, the first protrusion 350A can come into contact with the door 100 and the normal actuator 250N.

Even when the door 100 is going to be closed in a close direction indicated by an arrow, the first protrusion 350A of the protrusion 350 comes into contact with the door 100 and the normal actuator 250N, and it is possible to prevent the normal actuator 250N from coming closer to the main body frame 301 than a tip end position of the first protrusion 350A. Accordingly, the first protrusion 350A can maintain the state where the distance between the normal actuator 250N and the sensor main body 210 is longer than the detectable distance. Accordingly, the maintenance-use actuator 250M is detected, the maintenance mode is maintained, the driving of the internal device is maintained, and the display indicating that the maintenance work is being performed can be continued.

In the above description, it is assumed that the fixture 300 is not removed when the door 100 is closed, but the present invention is not limited thereto. For example, it is also assumed that when the door 100 is closed, the fixture 300 is removed depending on the strength of the force transmitted by the door 100 and the normal actuator 250N to the fixture 300 via the protrusion 350. For example, when the fixture 300 is constituted by the snap-fit structure or other structures, it is possible to assume the case where the fixture 300 is removed and the case where the fixture 300 is not removed.

For example, when a weak force (a force equal to or less than a predetermined value) is applied to the fixture 300, the fixture 300 may remain in a manner of being mounted to the sensor main body 210 without releasing the mounting to the sensor main body 210. In this case, the maintenance-use actuator 250M held by the fixture 300 is positioned inside the detection range achieved by the sensor main body 210. On the other band, the normal actuator 250N provided in the movable frame 112 of the closed door 100 is positioned outside the detection range achieved by the sensor main body 210 because the normal actuator 250N comes into contact with the protrusion 350 and is restrained from coming closer to the sensor main body 210. Accordingly, the fixture 300 can restrain the two actuators 250 from being simultaneously positioned within the detection range achieved by the sensor main body 210, and can restrain erroneous setting (for example, indefinite) of the operation mode. In this case, the operation mode is set to the maintenance mode based on the detection of the maintenance-use actuator 250M.

On the other hand, for example, when a strong force (a force larger than the predetermined value) is applied to the fixture 300, the fixture 300 may be removed by releasing the mounting to the sensor main body 210. In this case, the maintenance-use actuator 250M held by the fixture 300 is positioned outside the detection range achieved by the sensor main body 210. Instead, the normal actuator 250N provided in the movable frame 112 of the closed door 100 is positioned inside the detection range achieved by the sensor main body 210. Accordingly, it is possible to restrain the two actuators 250 from being simultaneously positioned within the detection range achieved by the sensor main body 210, and restrain the erroneous setting (for example, indefinite) of the operation mode. In this case, the operation mode is set to the normal mode based on the detection of the normal actuator 250N.

### <Material of Fixture>

Next, a material constituting the fixture 300 will be described.

The material constituting the fixture 300 is not particularly limited, but the fixture 300 is preferably made of a (elastically deformable) resin material capable of easily achieving elastic deformation. For example, the fixture 300 may be made of a material containing a light transmitting resin or a light diffusing resin. In this case, as illustrated in FIG. 7A, even when the fixture 300 and the light projection port 214 face each other, the light emitted from the light projection port 214 can pass through the fixture 300. Accordingly, even when the actuator 250M or the fixture 300 closes the light projection port 214 through which the sensor main body 210 emits the light, the fixture 300 can move around to the periphery of the actuator 250M (the RFID in the actuator 250) and guide the light due to the light transmissive property of the fixture 300, and can transmit the display of the sensor main body 210 to the outside. Accordingly, the worker can easily check the display of the sensor main body 210 (for example, the display indicating the maintenance mode) independently of the mounted state of the sensor main body 210 and the fixture 300, and the workability of the worker during the maintenance is improved.

In addition, the light transmitting resin or the light diffusing resin may be polyacetal (POM), for example. Therefore, the fixture 300 can ensure a certain degree of strength as well as the light transmissive property, and can restrain breakage of the fixture 300. For example, the fixture 300 can be easily attached and detached with respect to the sensor main body 210, and can be easily carried, and thus there is a possibility that the fixture 300 is handled somewhat roughly, but the failure of the fixture 300 can be restrained.

In addition, in the fixture 300, the first engaging portion 330 and the second engaging portion 340 are disposed at the end portions of the fixture 300 in the longitudinal direction. In the first engaging portion 330 and the second engaging portion 340, a spring or the like may be provided in order to obtain a sufficient biasing force, but a component such as the spring does not exist at a position facing the light projection port 214. Therefore, the fixture 300 can restrain the attenuation of the light emitted from the light projection port 214 caused by the emitted light passing through a large number of components.

As described above, according to the fixture 300, the actuator with a fixture 400, or the detection switch 200A (the fixture 300 and the like) of the present embodiment, it is possible to easily maintain a state where the maintenance-use actuator 250M is always close to the sensor main body 210 so as to not detect an abnormality even when the door 100 is continuously opened. Also in this case, by the fixture 300 and the like, it is not necessary for the worker to continuously hold the actuator 250M, and the burden on the worker can be reduced. Further, by the fixture 300 and the like, the determination of the presence-of-abnormality by the sensor main body 210 in the state where the door 100 is opened is avoided, and thus the driving of the internal device can be prevented from stopping. Accordingly, by the fixture 300 and the like, the smooth maintenance work can be achieved, and an increase in the burden on the worker can be restrained. Further, the worker can use the switch system 5 in the maintenance mode by mounting the fixture 300 to the sensor main body 210 during the maintenance work, and can use the switch system 5 in the normal mode by removing the fixture 300 from the sensor main body 210 in advance during a period in which the maintenance work is not performed.

### <Summary of Present Embodiment>

As described above, the fixture 300 according to the present embodiment mounts the maintenance-use actuator 250M to the sensor main body 210 of the detection switch 200. The fixture 300 includes the holding portion 302 that holds the actuator 250M communicating with the sensor main body 210 when the distance to the sensor main body 210 is within the predetermined distance. The fixture 300 includes the mounted portions 303 and 304 that can be detachably mounted to the sensor main body 210 in the state where the distance between the actuator 250M held by the holding portion 302 and the sensor main body 210 is maintained within the predetermined distance. The fixture 300 includes the main body frame 301 that connects the holding portion 302 and the mounted portions 303 and 304 and extends along the first direction (for example, the Y2 direction). The fixture 300 includes the protrusion 350 that projects and extends from the main body frame 301 along the third direction (for example, the X2 direction) perpendicular to the first direction and the second direction (for example, the Z2 direction) from the fixture 300 toward the sensor main body 210 in the mounted state where the fixture 300 is mounted to the sensor main body 210.

Therefore, by using the fixture 300, the actuator 250M always keeps the distance from the sensor main body 210 at a constant distance, and thus the actuator 250M is detected by the sensor main body 210. Accordingly, for example, even when no worker grips the actuator 250M and approaches the sensor main body 210, no abnormality is detected by the sensor main body 210 during the maintenance work, and thus at least a part of the driving of the internal device can be continued, and the maintenance work can be smoothly performed.

Further, even when the door 100 is going to be closed due to some reasons during the maintenance work and the normal actuator 250N provided in the movable frame 112 is going to approach the sensor main body 210 provided in the fixing frame 111, the distance between the sensor main body 210 and the normal actuator 250N is maintained at the constant distance or more due to the presence of the protrusion 350. As a result, it is possible to restrain the normal actuator 250N from entering the communication range achieved by the sensor main body 210 (the detection range of the actuator 250). It is possible to restrain the plurality of actuators 250 (a maintenance-use actuator 250M and the normal actuator 250:4) from simultaneously existing in the communication range achieved by the sensor main body 210. Accordingly, the fixture 300 can restrain the sensor main body 210 from making an erroneous determination regarding the operation based on these actuators 250 to be performed, or from being indefinite. Accordingly, the fixture 300 can support accurate setting of the operation mode by the sensor main body 210, can restrain a decrease in the detection accuracy of the abnormality detection, and can restrain the maintenance work from becoming difficult due to the erroneous stopping of the driving of the internal device. As described above, the fixture 300 can restrain erroneous detection of the detection switch 200 during the maintenance work inside the door 100 to which the detection switch 200 is mounted, and can support the smooth progress of the maintenance work.

In addition, the protrusion 350 may include the first protrusion 350A extending from the main body frame 301 toward one side in the third direction, and the second protrusion 350B extending from the main body frame 301 toward the other side in the third direction.

Therefore, in the fixture 300, the first protrusion 350A and the second protrusion 350B project in both directions of the positive side and the negative side in the third direction. Accordingly, even when the door 100 exists on either side in the third direction, the fixture 300 can suitably maintain the distance between the normal actuator 250N provided corresponding to the door 100 and a sensor main body 210.

Further, the first protrusion 350A and the second protrusion 350B may have different lengths along the third direction.

Therefore, in a case where the door 100 is going to be closed even when a mounting position of the sensor main body 210 in the sensor main body 210 is not at the center in the third direction (the X2 direction) but is disposed closer to either end side, in the fixture 300, the first protrusion 350A or the second protrusion 350B can reliably come into contact with the door 100 independently of the mounting direction of the fixture 300. Accordingly, it is possible to restrain the normal actuator 250N provided corresponding to the door 100 from entering the detection range achieved by the sensor main body 210.

In addition, the protrusion 350 may have a substantially trapezoidal shape that increases in diameter from the tip end toward the base end of the protrusion 350.

When performing the maintenance work, the worker may bring the fixture 300 to a site and mount the fixture 300 to the sensor main body 210. In this case, even when the worker takes the fixture 300 in and out of an accommodation tool (a pocket and the like), the fixture 300 is less likely to be caught by the accommodation tool, and the portability and the mountability of the fixture 300 are improved. In addition, at the time of molding the fixture 300, a molded article is easily removed from a metal mold and is easily manufactured.

Further, the fixture 300 may have a longitudinal direction. The mounted portions 303 and 304 may include the first engaging portion 330 that is provided at the one end of the fixture 300 in the longitudinal direction and is engaged with the one end 216 of the sensor main body 210 in the longitudinal direction, and the second engaging portion 340 that is provided at the other end of the fixture 300 in the longitudinal direction and is engaged with the other end 217 of the sensor main body 210 in the longitudinal direction, respectively. The first engaging portion 330 and the second engaging portion 340 may be engaged with the one end 216 and the other end 217 of the sensor main body 210 in the longitudinal direction by the biasing forces in the directions approaching each other, respectively.

Therefore, the fixture 300 has the snap-fit structure, and thus the sensor main body 210 can be easily attached and detached. Accordingly, depending on the magnitude of a pressing force applied to the fixture 300, the fixture 300 is removed or not removed from the sensor main body 210. For example, in the case where the door 100 is pressed by the force equal to or less than the predetermined value when the door 100 is in contact with the fixture 300, the fixture 300 remains without being removed from the sensor main body 210, and the normal actuator 250N provided in the movable frame 112 of the door 100 does not enter the detection range achieved by the sensor main body 210. Accordingly, the maintenance-use actuator 250M is detected, and the maintenance mode is set. On the other hand, in the case where the door 100 is pressed by the force larger than the predetermined value when the door 100 is in contact with the fixture 300, the fixture 300 is removed from the sensor main body 210, and the normal actuator 250N provided in the movable frame 112 of the door 100 enters the detection range achieved by the sensor main body 210. Accordingly, the normal actuator 250N is detected, and the normal mode is set. Therefore, the operation mode is set to one mode, and the fixture 300 can restrain the operation mode from the erroneous setting, or from being indefinite.

In addition, the actuator with a fixture 400 includes the fixture 300 and the actuator 250M held by the holding portion 302. The actuator with a fixture 400 can independently flow separately from the detection switch 200A, and can be carried by the worker. The worker can carry and use the actuator with a fixture 400 in various sites.

Further, the detection switch 200A includes the sensor main body 210 and the actuator with a fixture 400. Even when the door 100 is opened during the maintenance work, the detection switch 200A can prevent the determination of the presence-of-abnormality, continue the driving of the internal device, and achieve the smooth maintenance work.

Although various embodiments have been described above with reference to the drawings, it is needless to say that the present invention is not limited to these embodiments. It is apparent that a person skilled in the art can conceive of various modifications and alterations within the scope described in the claims, and it is understood that such modifications and alterations naturally fall within the technical scope of the present invention. In addition, the constituent elements in the above embodiment may be freely combined without departing from the scope of the invention.

For example, in the embodiment described above, the first protrusion 350A and the second protrusion 350B have the same length along the X2 direction, and the protrusions may extend symmetrically on both sides in the X2 direction.

In addition, the detection switch 200A may not shift to the maintenance mode without regard to the operation mode particularly. In this case, since the actuator 250M held by the fixture 300 is always detected by the sensor main body 210, the driving of the internal device may be continued without detecting an abnormality. Even in this case, the worker can perform the maintenance work.

For example, it is described in the embodiment described above that the fixture 300 deviates from the center of the sensor main body 210 and is mounted to the sensor main body 210, but the present invention is not limited thereto. Since the fixture 300 is mounted to the sensor main body 210 in the vicinity of the center of the sensor main body 210, a mounted portion of the sensor main body 210 may have symmetry, and the fixture 300 may be mounted to the sensor main body 210 from any direction in the same manner.

The present application is based on Japanese Patent Application No. 2021-110857 filed on Jul. 2, 2021, and the contents thereof are incorporated herein by reference.

### INDUSTRIAL APPLICABILITY

The present disclosure is useful for, for example, a fixture, an actuator with a fixture, and a detection switch, and by using the fixture, the actuator with a fixture, and the detection switch, erroneous detection of the detection switch can be restrained during the maintenance work performed inside the door to which the detection switch is mounted, and the maintenance work can be smoothly progressed.

### REFERENCE SIGNS LIST

5 switch system
10 door-attached device
100 door
111 fixing frame
112 movable frame
113 door main body
200 detection switch
200A detection switch
210 sensor main body
211 processor
212 coil
213 light source
214 light projection port
216 one end of sensor main body
217 other end of sensor main body
218 memory
219 input and output unit
221, 221a, 221b, and 221c recess portion
223, 223a, and 223b ridge
231 end surface
233 projecting portion
234, 234a, 234b, 234c, and 234d projection piece
250, 250M, 250N actuator
280 RFID Tag
300 fixture
301 main body frame
302 holding portion
303.304 mounted portion
305 first beam portion
306 second beam portion
307 projection
330 first engaging portion
332 first engaging portion wall
334 tip protrusion
336 semicircular arc-shaped surface
338 locking piece
340 second engaging portion
341 second engaging portion wall
342, 342a, and 342b first engaging convex portion
343, 343a, and 343b second engaging convex portion
344 first gap
345 second gap
350 protrusion
350A first protrusion
350B second protrusion
400 actuator with fixture

1. A fixture for mounting a maintenance-use actuator to a sensor main body of a detection switch, comprising:
a holding portion configured to hold the actuator that communicates with the sensor main body when a distance to the sensor main body is within a predetermined distance;
a mounted portion detachably mounted to the sensor main body in a manner of maintaining the distance between the actuator held by the holding portion and the sensor main body within the predetermined distance;
a main body frame connecting the holding portion and the mounted portion and extending along a first direction; and
a protrusion protruding and extending from the main body frame along a third direction perpendicular to the first direction and a second direction from the fixture toward the sensor main body in a mounted state where the fixture is mounted to the sensor main body.

2. The fixture according to claim 1, wherein
the protrusion includes
a first protrusion extending from the main body frame toward one side in the third direction; and
a second protrusion extending from the main body frame toward the other side in the third direction.

3. The fixture according to claim 2, wherein
the first protrusion and the second protrusion have different lengths along the third direction.

4. The fixture according to claim 1, wherein
the protrusion has a substantially trapezoidal shape that increases in diameter from a tip end of the protrusion toward a base end of the protrusion.

5. The fixture according to claim 1, wherein
the fixture has a longitudinal direction,
the mounted portion includes
a first engaging portion provided at one end of the fixture in the longitudinal direction and engaged with one end of the sensor main body in a longitudinal direction; and
a second engaging portion provided at the other end of the fixture in the longitudinal direction and engaged with the other end of the sensor main body in the longitudinal direction, and
the first engaging portion and the second engaging portion are engaged with one end of the sensor main body in the longitudinal direction and the other end of the sensor main body in the longitudinal direction by biasing forces in directions approaching each other, respectively.

6. The fixture according to claim 1, wherein
the sensor main body has a light source, and
the fixture is made of a material containing a light transmitting resin or a light diffusing resin.

7. The fixture according to claim 6, wherein
the light transmitting resin or the light diffusing resin is an elastically deformable resin.

8. An actuator with a fixture, comprising:
the fixture according to claim 1; and
the actuator held by the holding portion of the fixture.

9. A detection switch, comprising:
the sensor main body; and
the actuator with the fixture according to claim 8.
